(19) United States
(12) Patent Application Publication
(10) Pub. No.: US 2026/0084304 A1
(43) Pub. Date: Mar. 26, 2026

(54) Teaching Method for Substrate Transfer Device and Substrate Processing Apparatus

(71) Applicant: Tokyo Electron Limited, Tokyo (JP)

(72) Inventors: Kosuke KINOSHITA, Tokyo (JP); Takashi SUGIMOTO, Yamanashi (JP)

(21) Appl. No.: 19/329,284

(22) Filed: Sep. 15, 2025

(30) Foreign Application Priority Data
Sep. 24, 2024 (JP) 2024-165613

(51) Int. Cl. B25J 9/16; B25J 11/00; H01L 21/67; H01L 21/687

(52) U.S. Cl. CPC B25J 9/1664; B25J 11/0095; H10P 72/0606; H10P 72/7602; H10P 72/7612; G05B 2219/39001

(57) ABSTRACT

There is a teaching method for a substrate transfer device is disclosed. The method includes moving a transfer arm to multiple set positions along a reference axis selected from multiple axes extending through a center and a periphery of a placing surface, and executing at each set position a cycle comprising: moving the transfer arm holding a substrate at a preset holding position; transferring the substrate from the arm to a placing table via lift pins; receiving the substrate back by the arm via the lift pins; and detecting a new holding position of the substrate. Based on the new holding position, it is determined whether the substrate was mounted on an edge portion. A target position for transfer from the arm to the placing table is determined according to the set positions for the reference axes, and the target position is set as the arm's set position.

### CROSS-REFERENCE TO RELATED APPLICATIONS

This application claims priority to Japanese Patent Application No. 2024-165613 filed on Sep. 24, 2024, the entire contents of which are incorporated herein by reference.

### TECHNICAL FIELD

The present disclosure relates to a teaching method for a substrate transfer device and a substrate processing apparatus.

### BACKGROUND

In a manufacturing process of a semiconductor device, a wafer, which is a semiconductor substrate, is placed on a placing table, and processing such as forming a metal film is performed. Such processing may be performed in a state where the wafer is placed on the placing table provided in a processing chamber.

Japanese Patent No. 2885502 discloses a hot plate configured as a substrate placing table on which a wafer is placed in an adhesion processing apparatus for improving adhesion between a resist and a wafer. Regarding the placement of the wafer on the hot plate, a transfer arm disposed outside the adhesion processing apparatus supports the wafer and positions it above the hot plate. Next, support pins protrude from the surface of the hot plate to receive the wafer from the transfer arm, and is lowered to place the wafer on the hot plate.

### SUMMARY

The present disclosure provides a technique for teaching a set position of a transfer arm capable of appropriately/properly locating a substrate on a placing table of a substrate processing apparatus.

In accordance with an exemplary embodiment of the present disclosure, there is a teaching method for a substrate transfer device, wherein the substrate device includes a transfer arm configured to transfer a substrate, a driving mechanism configured to move the transfer arm, and a driving controller configured to control the driving mechanism such that the transfer arm moves to a set position that is preset in advance, and wherein a placing table has a placing surface on which the substrate is placed, an edge portion that protrudes from the placing surface along a periphery of the placing surface, and a lift pin configured to protrude and retract with respect to the placing surface and transfer the substrate between the placing surface and the transfer arm, when the substrate is transferred by the transfer arm with respect to the placing table, the method comprises: moving the set position multiple times along one reference axis selected from a plurality of reference axes, which are set to pass through a center and a periphery of the placing surface and extend in different directions, and executing, at each set position, a cycle including the following steps (a) to (d): (a) moving the transfer arm holding the substrate at a preset holding position toward one set position; (b) transferring the substrate from the transfer arm that has moved to the one set position to the placing table via the lift pin; (c) receiving the substrate by the transfer arm, from the placing table to which the substrate has been transferred, via the lift pin; and (d) detecting a new holding position of the substrate after the substrate is received by the transfer arm from the placing table; determining whether or not the substrate was mounted on the edge portion in step (b) of the cycle, based on the new holding position detected in step (d); specifying a target position where the substrate is transferred from the transfer arm to the placing table, based on the one set position for each of the plurality of reference axes when it is determined that the substrate was mounted on the edge portion; and causing the driving controller to set the target position as the set position of the transfer arm.

### BRIEF DESCRIPTION OF THE DRAWINGS

FIG. 1 is a plan view illustrating a substrate processing apparatus according to an embodiment.

FIG. 2 is a plan view showing a holding part of a transfer mechanism.

FIG. 3 is a longitudinal side view of a vacuum transfer chamber and a film forming module.

FIG. 4 is a block diagram showing the substrate processing apparatus and a controller.

FIG. 5 is a plan view showing a line sensor and a holding part for holding a substrate.

FIG. 6A is a longitudinal side view showing the holding part and lift pins in the case of placing a substrate.

FIG. 6B is a longitudinal side view showing the holding part and the lift pins in the case of placing a substrate.

FIG. 7A is a longitudinal side view showing a substrate placed by the holding part at a first position.

FIG. 7B is a longitudinal side view showing a substrate placed by the holding part at a second position.

FIG. 7C is a longitudinal side view showing a substrate placed by the holding part at a third position.

FIG. 8 is a diagram showing four reference axes for identifying a boundary position.

FIG. 9 is a diagram showing a procedure of an operation of determining a target position of a holding part 16.

FIG. 10 is a flowchart showing cycle steps performed in an operation of identifying the boundary position in each reference axis.

FIG. 11A is a diagram showing an operation of identifying a boundary position in a first cycle step in the 0° direction.

FIG. 11B is a diagram showing an operation of identifying a boundary position in a second cycle step in the 0° direction.

FIG. 11C is a diagram showing an operation of identifying a boundary position in an N^{th} cycle step in the 0° direction.

FIG. 11D is a diagram showing an operation of identifying a boundary position in a first cycle step in the 180° direction.

FIG. 11E is a diagram showing an operation of identifying a boundary position in an N^{th} cycle step in the 180° direction.

FIG. 12A is a diagram showing a boundary position identifying operation of a first cycle step in the 90° direction.

FIG. 12B is a diagram showing the boundary position identifying operation of a second cycle step in the 90° direction.

FIG. 12C is a diagram showing the boundary position identifying operation of an N^{th} cycle step in the 90° direction.

FIG. 12D is a diagram showing the boundary position identifying operation of a first cycle step in the 270° direction.

FIG. 12E is a diagram showing the boundary position identifying operation of an N^{th} cycle step in the 270° direction.

FIG. 13 is a diagram showing the boundary position identifying operation of the N^{th} cycle step in the 270° direction.

FIG. 14 is a plan view showing a modification of a substrate processing apparatus 1.

FIGS. 15A and 15B are first diagrams showing a case in which a deviation amount D may be smaller than a taper width L.

FIGS. 16A and 16B are second diagrams showing a case in which the deviation amount D may be smaller than the taper width L.

FIG. 17 is a diagram showing the boundary position identifying operation in a second embodiment.

FIG. 18 is a diagram showing the boundary position identifying operation in first and second modifications of the second embodiment.

FIG. 19 is a flowchart showing a procedure of an operation of determining a target position in a third embodiment.

FIG. 20 is a flowchart showing a procedure of an operation of determining a target position in a modification of the third embodiment.

FIG. 21 is a graph showing test results of Test 1.

FIG. 22 is a graph showing test results of Test 2.

FIG. 23 shows Tables (1) and (2) summarizing test results of Test 3.

FIG. 24 shows Tables (1) and (2) summarizing test results of Test 4.

FIG. 25 shows Tables (3) to (7) summarizing test results of Test 4.

FIG. 26 shows Table (8) summarizing test results of Test 4.

### DETAILED DESCRIPTION

### First Embodiment

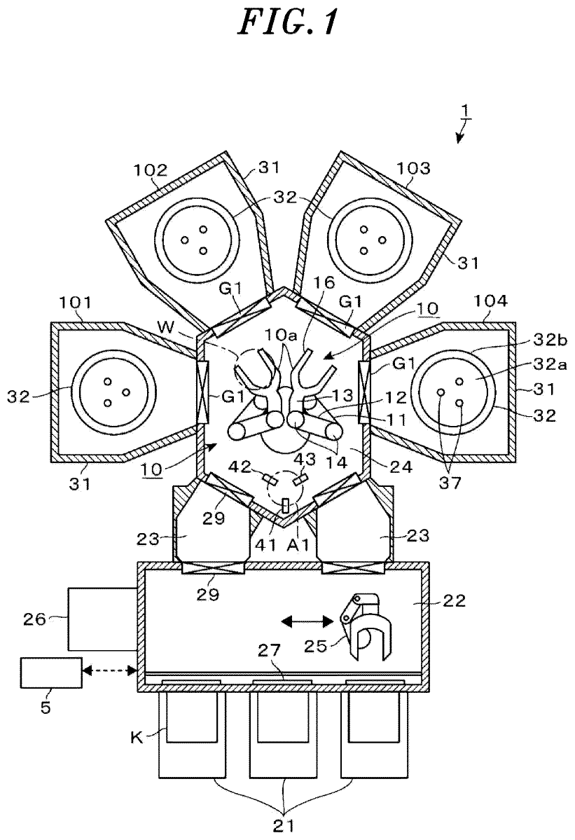

FIG. 1 is a plan view illustrating a substrate processing apparatus according to a first embodiment. The substrate processing apparatus 1 is configured as a multi-chamber vacuum processing system including film forming modules 101 to 104 for forming a film on a substrate W and a vacuum transfer chamber (transfer module) 24 for transferring a substrate W to the film forming modules 101 to 104.

The substrate processing apparatus 1 includes an atmospheric pressure transfer chamber 22 of which inner space is maintained at an atmospheric pressure, for example. A load port 21 for transferring a substrate W between the chamber 22 and a transfer container K containing substrates W is provided in front of the atmospheric pressure transfer chamber 22. A door 27 is provided on the front wall of the atmospheric pressure transfer chamber 22, and is opened when the substrate W is transferred between the chamber 22 and the transfer container K. A transfer mechanism 25 for transferring a substrate W is provided in the atmospheric pressure transfer chamber 22.

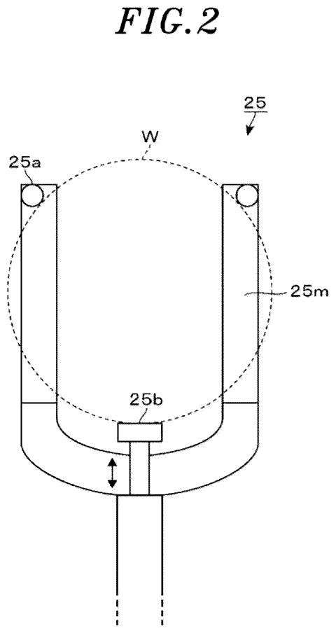

FIG. 2 is a plan view showing a holding portion 25m of the transfer mechanism 25 holding a substrate W. The transfer mechanism 25 has a structure similar to that of the transfer mechanism 10 to be described later. In the transfer mechanism 25, a placing surface for the substrate W, two regulating protrusions 25a provided on the tip end side of the placing surface, and a pressing portion 25b provided on the base end side of the placing surface are formed on the upper surface side of the U-shaped holding part 25m, thereby providing an edge grip function. The transfer mechanism 25 is configured such that the pressing portion 25b is moved toward the regulating protrusions 25a in a state where the substrate W is transferred onto the placing surface, and the holding position of the substrate W is regulated by the regulating protrusions 25a and the pressing portion 25b. In this manner, by holding the substrate W pressed against the two regulating protrusions 25a, the transfer mechanism 25 holds the substrate W in a state where the center of the substrate W is positioned on a preset position such as the center of the holding part 25m in plan view, for example.

Further, as viewed from the load port 21 side, an alignment chamber 26 for adjusting the orientation or eccentricity of the substrate W is provided on the left wall of the atmospheric pressure transfer chamber 22. In the alignment chamber 26, the orientation of the substrate W or the transfer position with respect to the transfer mechanism 25 is determined based on a notch (not shown) or orientation flat (not shown) formed at the periphery of the substrate W. For example, in the case of determining the orientation of the substrate W based on the notch, in the alignment chamber 26, the radial direction from the tip end of the V-shaped cutout of the notch is set as 0°, and the transfer mechanism 25 receives the substrate W such that the center of the substrate W is aligned with a preset position.

Two load-lock chambers 23 arranged side by side are connected to the wall opposite to the load port 21 as viewed from the atmospheric pressure transfer chamber 22. The load-lock chamber 23 has a function of switching an inner atmosphere between an atmospheric atmosphere and a vacuum atmosphere while accommodating the substrate W therein. When viewed from the atmospheric pressure transfer chamber 22, the vacuum transfer chamber 24 is located at the rear side of the load-lock chambers 23. The atmospheric pressure transfer chamber 22 and the vacuum transfer chamber 24 are connected to the load-lock chambers 23 via gate valves 29.

The vacuum transfer chamber 24 is connected to an exhaust mechanism (not shown) and has an inner space maintained in a vacuum atmosphere. For example, the four film forming modules 101 to 104 are connected to the sidewall of the vacuum transfer chamber 24. In addition, line sensors 41 to 43 and two transfer mechanisms 10 are provided in the vacuum transfer chamber 24, for example, and the transfer mechanisms 10 transfers the substrate W to the film forming modules 101 to 104 and the load-lock chambers 23.

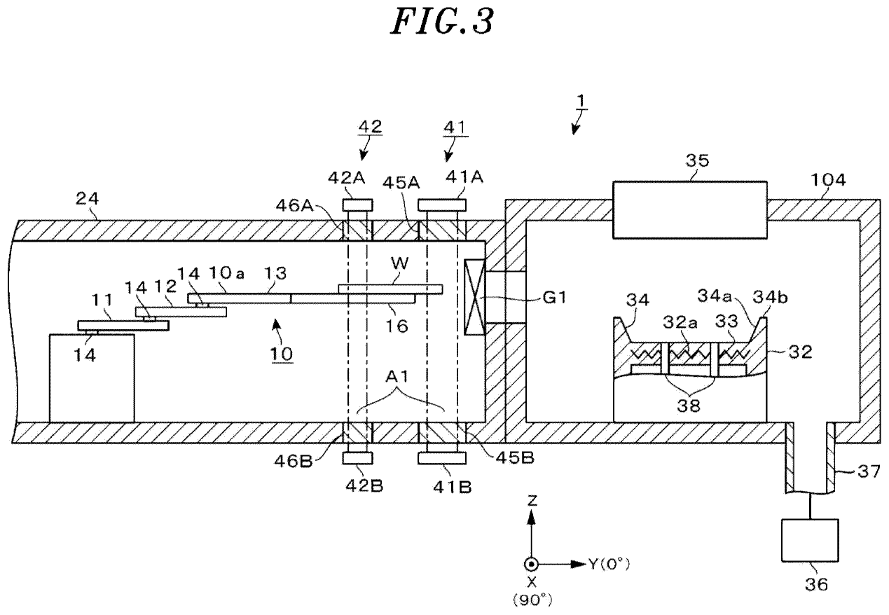

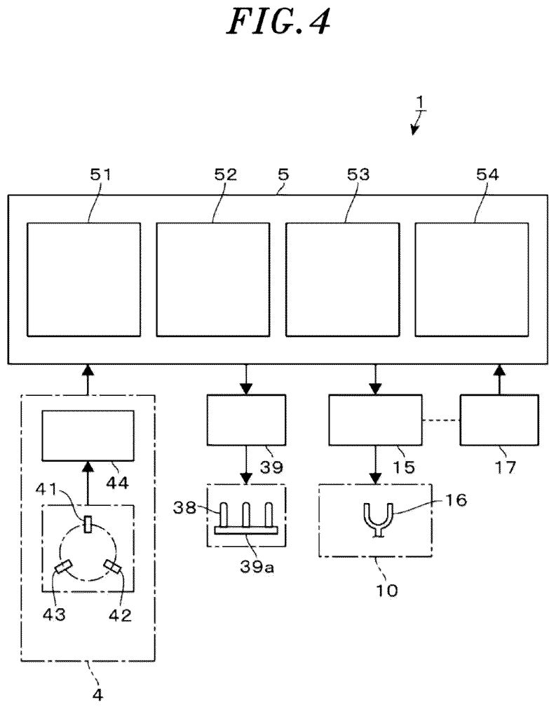

FIG. 3 is a longitudinal side view of the vacuum transfer chamber 24 and the film forming module 104, and FIG. 4 is a block diagram showing the substrate processing apparatus 1 and a controller 5. In FIG. 3, for convenience of illustration, the line sensors 41 to 43 located on the load-lock chamber 23 side in the vacuum transfer chamber 24 in FIG. 1 are illustrated on the film forming module 104 side, and only two line sensors 41 and 42 are illustrated.

Each transfer mechanism 10 includes a transfer arm 10a configured as a multi-joint arm. For example, the transfer arm 10a includes a lower arm member 11, an intermediate arm member 12, an upper arm member 13, and a rotation shaft 14 provided on the base side of each of the arm members 11 to 13. The respective rotating shafts 14 are connected to a rotation mechanism (not shown), and rotate individually to rotate the respective arm members 11 to 13. By combining the above operations, the upper arm member 13 can move along desired trajectory while performing rotational movement and linear movement. In addition, the holding part 16 for holding the substrate W to be transferred is provided on the tip end side of the upper arm member 13.

The transfer arm 10a may include an extension/contraction mechanism, and the upper arm member 13 may be extended/contracted to increase the linear movement distance. The extension/contraction mechanism and the rotation mechanism constitute the driving mechanism of the transfer arm 10a, and a pulse encoder 17 (see FIG. 4) is connected to a motor (not shown) for driving the driving mechanism. The transfer arm 10a is connected to a driving controller 15. Further, the driving controller 15 manages coordinates (hereinafter, also referred to as “driving system coordinates”) for identifying the position of the holding part 16, and controls the rotation mechanism to move the holding part 16 to a set position to be described later.

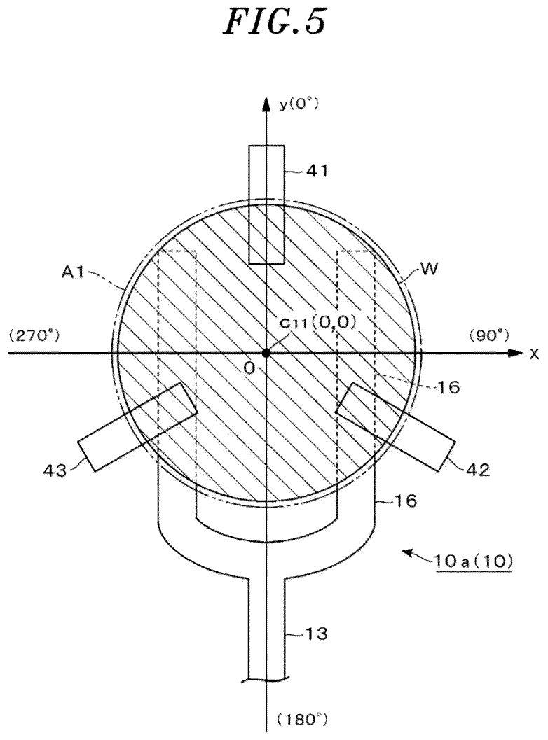

The holding part 16 is provided on the tip end side of the upper arm member 13, and is configured to transfer the substrate W while holding the substrate W horizontally. The holding part 16 has a U-shape that is bifurcated toward the tip end when viewed from the base end side of the upper arm member 13 in plan view, as shown in FIG. 5 to be described later. By locating the substrate W in the holding area including the upper surface of the holding part 16, the substrate W can be supported horizontally. The holding area is configured such that the substrate W can be appropriately held by effectively suppressing the positional deviation of the substrate W in the central area. The substrate W appropriately held in the holding area is located such that the center C of the substrate W is aligned with the center of the holding area. Hereinafter, the position where the substrate W can be appropriately held may be referred to as “appropriate holding position,” and the appropriate holding position corresponds to a preset holding position in the claims.

The holding part 16 is managed by the driving controller 15 and the pulse encoder 17 based on the center position of the holding area, for example, in the form of polar coordinates (r, θ) with the rotation axis 14 of the lower arm member 11 as the origin. The polar coordinates are correlated with the driving system coordinates of the driving controller 15. The transfer mechanism 10 configured as described above can move the holding part 16 to a desired position on the driving system coordinates.

As shown in FIGS. 1, 3, and 5, the three line sensors 41 to 43 are configured to detect the position of the substrate W held by the holding part 16. The line sensors 41 to 43 include a pair of light emitting parts 41A to 43A and light receiving parts 41B to 43B, respectively. The light emitting parts 41A to 43A and the light receiving parts 41B to 43B are provided on the ceiling side and the floor side of the housing of the vacuum transfer chamber 24 to face each other in the vertical direction, for example. Specifically, the light emitting parts 41A to 43A are provided on the upper surfaces of light transmitting windows 45A to 47A made of, e.g., quartz, and provided on the ceiling portion of the vacuum transfer chamber 24. The light receiving parts 41B to 43B are provided on the bottom surfaces of the light transmitting windows 45B to 47B made of, e.g., quartz, and provided on the floor portion of the vacuum transfer chamber 24 to face the light emitting parts 41A to 43A.

FIG. 5 is a plan view showing the holding part 16 for holding the substrate W and the line sensors 41 to 43. The XY coordinates in FIG. 5 are relative coordinates in which the origin is set at the center of a measurement area A1 to be described later, and the Y axis is set to the direction in which the peripheral edge of the substrate W on the 0° side faces when the substrate W that has been aligned in the alignment chamber 26 is appropriately held in the holding area of the holding part 16. The light emitting parts 41A to 43A and the light receiving parts 41B to 43B of the line sensors 41 to 43 are spaced apart from each other at positions corresponding to the periphery of the measurement area A1 in plan view. Each of the light emitting parts 41A to 43A is configured to irradiate light in a band area extending from the inside to the outside of the measurement area A1, and each of the light receiving parts 41B to 43B receives the irradiated light at a position corresponding to the band area. With this configuration, when the holding part 16 is located in the measurement area A1 in a state where the substrate W is held in the holding area, the line sensors 41 to 43 can detect three different positions along the periphery of the substrate W in the band area. Further, a position calculation part 44 (see FIG. 4) connected to the line sensors 41 to 43 calculates the position (X, Y) of the center C of the substrate W from the three detected positions. The position of the measurement area A1 is stored in advance in the driving controller 15.

By using the line sensors 41 to 43 arranged in a band shape, even if the substrate W is held by the holding part 16 while being shifted from an appropriate holding position, the center position of the substrate W in that state can be calculated. The position calculation part 44 constitutes the position detector (position detection mechanism) 4 (see FIG. 4) together with the line sensors 41 to 43.

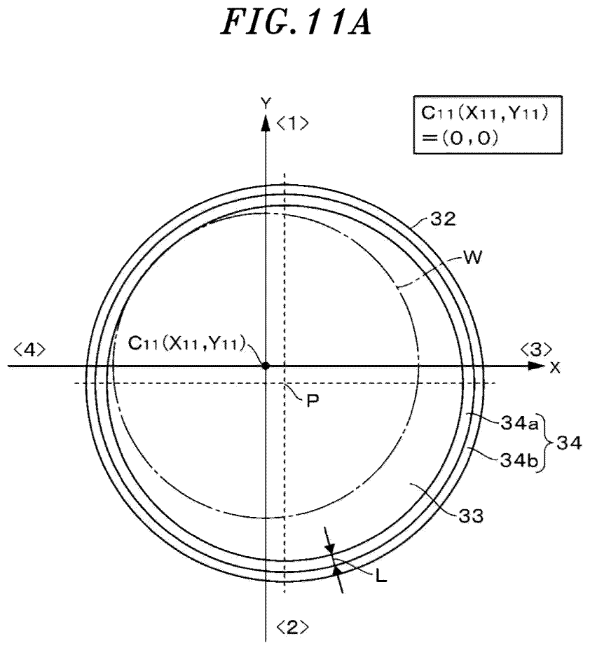

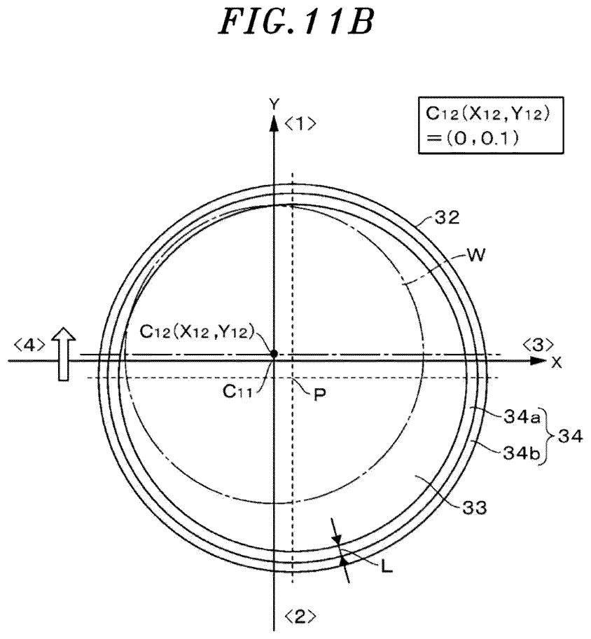

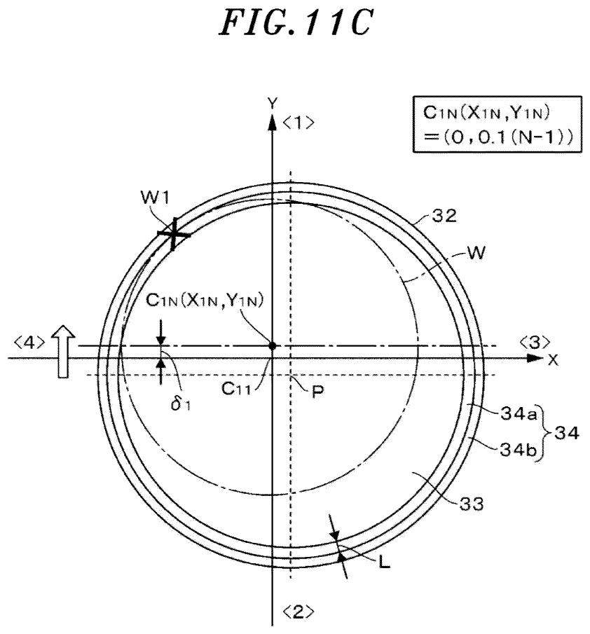

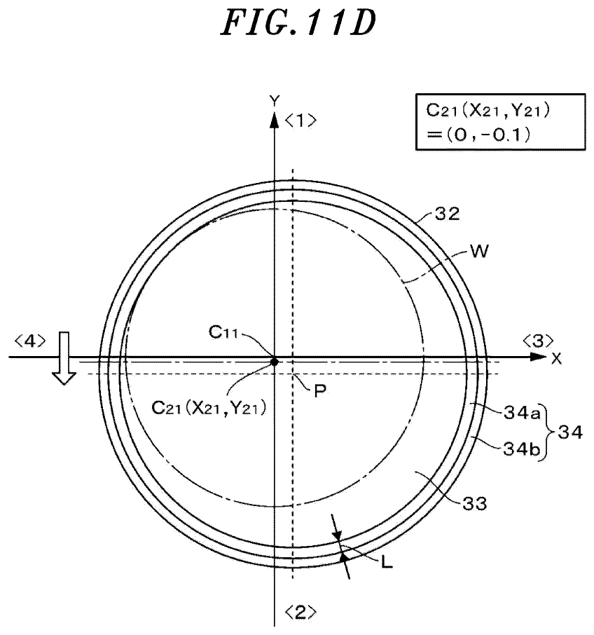

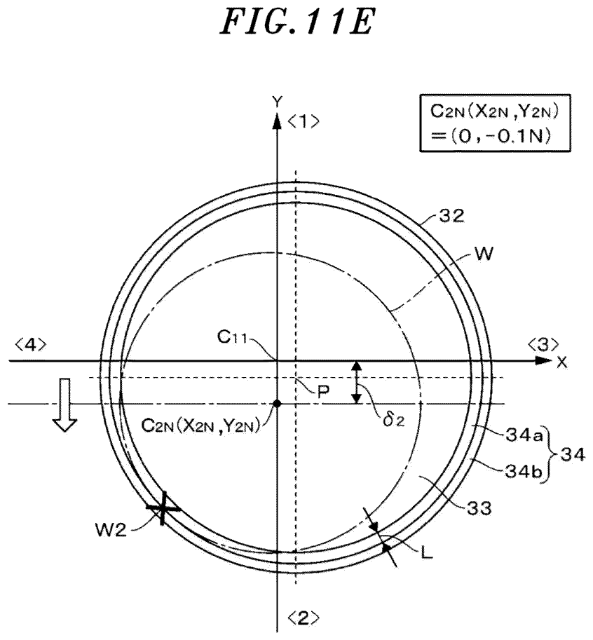

In this example, the film forming modules 101 to 104 are configured to form the same metal film. The configuration of the film forming module 104 will be representatively described in brief. As illustrated in FIGS. 1 to 3, the film forming module 104 includes a processing chamber 31 connected to the housing of the vacuum transfer chamber 24 via a gate valve G1. The processing chamber 31 has a loading/unloading port for loading/unloading the substrate W, and the gate valve G1 opens and closes the loading/unloading port. Further, in the processing chamber 31, a placing table 32 is provided at the rear side as viewed from the gate valve G1 side. In the first embodiment, when the substrate W is loaded through the loading/unloading port, the 0° direction of the substrate W is directed to the tip end in the traveling direction. In this example, the driving system coordinates managed by the driving controller 15 are an XYZ coordinate system in which the Y axis is set to follow the 0° radial direction of the substrate W when the substrate W is loaded into the film forming module 104, as shown in FIG. 3. Specifically, the origin of the driving system coordinate system is set at a position aligned with a center C₁₁ of the substrate W held by the holding part 16 in the “initial setting position” to be described later in FIG. 11A.

As shown in FIG. 3, a shower head 35 for supplying a processing gas is provided at the ceiling portion of the processing chamber 31 to face the placing table 32. The processing gas is supplied into the processing chamber 31 from a gas supply system (not shown) through the shower head 35. An exhaust line 37 provided with a vacuum pump 36 is connected to the bottom portion of the processing chamber 31.

The placing table 32 is located at the bottom portion of the processing chamber 31 of the film forming module 104. As shown in FIG. 3, a heater 32a, which is a resistance heating element, is embedded in the placing table 32. Further, the upper surface of the placing table 32 has a placing surface 33 for placing the substrate W thereon, and an edge portion 34 that protrudes from the placing surface 33 along the periphery of the placing surface 33. The placing surface 33 is a circular surface that is greater than the backside of the substrate W, and is, e.g., a smooth surface with relatively small surface roughness.

The edge portion 34 is formed in an annular shape to form a concentric circle with the placing surface 33. Further, the edge portion 34 has a flat upper end portion 34b, and a tapered surface 34a that becomes gradually lower from the upper end portion 34b toward the placing surface 33 on the inner periphery side facing the placing surface 33. Therefore, the tapered surface 34a and the upper end portion 34b that constitute the edge portion 34 are also provided concentrically with the placing surface 33. Further, the placing table 32 is provided with, e.g., three lift pins 38 capable of protruding or recessed with respect to the placing surface 33. The three lift pins 38 are provided at a lift plate 39a that is raised and lowered by a lift mechanism 39 (see FIG. 4), and are raised and lowered at simultaneously.

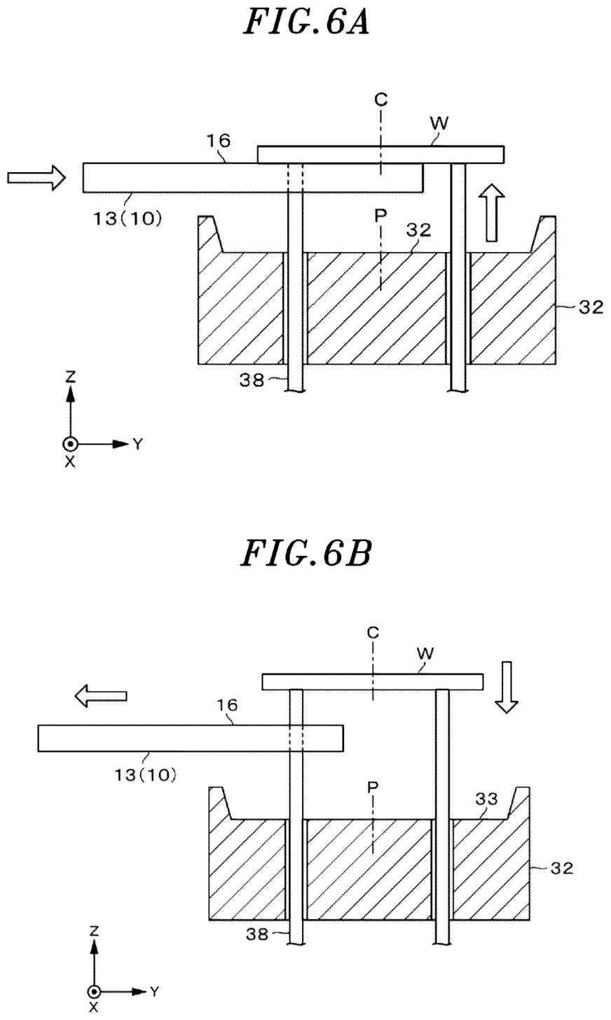

FIGS. 6A and 6B are longitudinal side views showing the holding part 16 and the lift pins 38 in the case of placing the substrate W on the placing table 32. In the case of placing the substrate W on the placing table 32, the transfer mechanism 10 causes the holding part 16 holding the substrate W to stand by in advance at a standby position outside the gate valve G1. Then, as shown in FIG. 6A, the transfer mechanism 10 causes the upper arm member 13 to move linearly into the processing chamber 31, and locates the holding part 16 at “set position” that is set in advance. The set position will be described later. Next, the protruded lift pins 38 lift up and support the backside of the substrate W, and receive the substrate W. In this case, the lift pins 38 are provided at positions that pass through the U-shaped inner space of the holding part 16 in plan view so as not to interfere with the holding part 16.

Next, as shown in FIG. 6B, when the holding part 16 moves in a direction opposite to the direction in which it is loaded into the processing chamber 31 and retracts from the processing chamber 31, the lift pins 38 are lowered and place the substrate W on the placing surface 33 of the placing table 32. Then, when the film forming process performed by the film forming module 104 is completed, the lift pins 38 transfer the substrate W from the placing table 32 to the holding part 16 by the reverse operation of the operation of placing the substrate W, and the holding part 16 retracts from the processing chamber 31. In this manner, the lift pins 38 can transfer the substrate W between the transfer mechanism 10 and the placing table 32.

In the placing operation, the set position of the holding part 16 needs to be the position where the substrate W transferred to the placing table 32 is placed within the placing surface 33. In the first embodiment, the “set position” of the holding part 16 is set such that the center C of the substrate W held by the holding part 16 is aligned with the center P of the placing surface 33 in plan view. However, in the substrate processing apparatus 1, the controller 5 and the driving controller 15 do not recognize the exact position of the center P of the placing surface 33. For example, when the processing chamber 31 is opened and the maintenance is performed on the placing table 32 or the lift pins 38, the position of the center of the placing table 32 and the position of the substrate W transferred to the placing table 32 via the lift pins 38 may change.

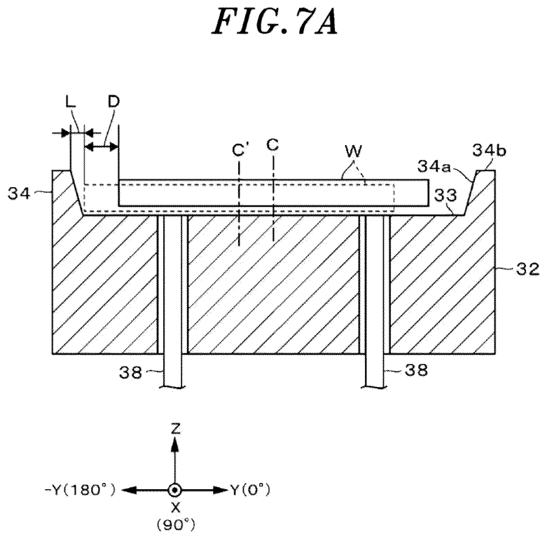

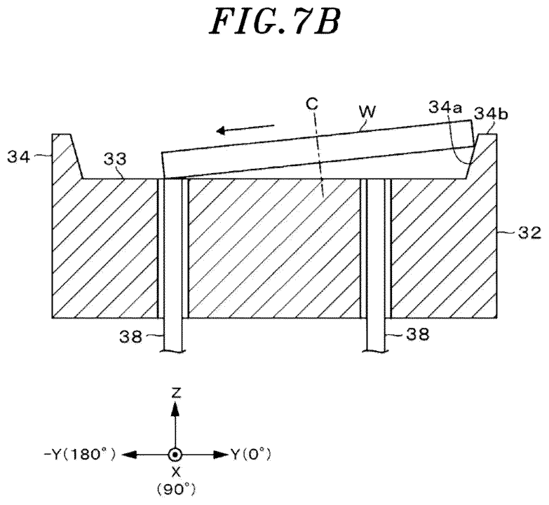

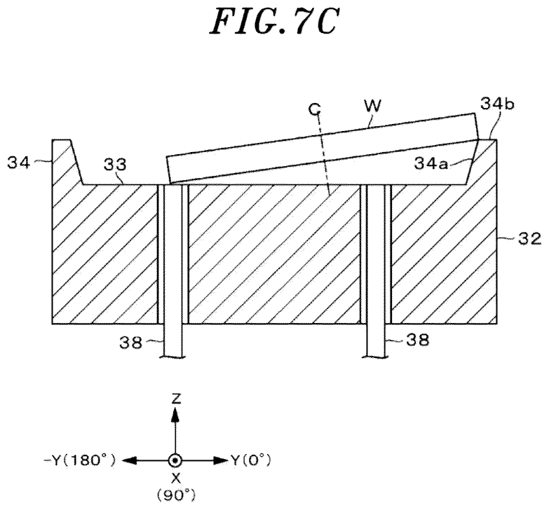

Therefore, before the film forming process is started, the substrate processing apparatus 1 specifies the center P of the placing surface 33 in advance. Then, the holding part 16 is positioned above the center P, and a substrate transfer target position (target position) where the substrate W can be transferred to the placing surface 33 via the lift pins 38 is identified. It becomes necessary to perform teaching to the driving controller 15 in order to set the target position to coincide with the above-described set position. For example, it is assumed that the diameter of the substrate W is 300 mm, the diameter of the placing surface 33 is 302 mm, and the width of the tapered surface 34a is 0.35 mm. In this case, the center of the substrate W is transferred to a position shifted by 1.4 mm from the center P of the placing surface 33, and the film formation is performed in a state where substrate W is located on the edge portion 34 as shown in FIG. 7C to be described later. In this manner, when a film is formed on the substrate W of which backside is not entirely in contact with the placing surface 33, the temperature cannot be adjusted uniformly in the surface. Accordingly, the uniformity of the thickness of the deposited film may deteriorate, or a film may be formed even on the backside of the substrate W. Therefore, it is important to accurately recognize the center P of the placing surface 33 and perform teaching.

In this regard, it is considered to adopt a method in which the processing chamber 31 is opened, an operator measures the exact position of the center P of the placing surface 33 and manually locates the substrate W such that the center of the substrate W coincides with the measured center P, and teaching is performed based on the result obtained after the substrate W is received at the holding part 16, for example. Alternatively, it is also considered to adopt a method in which a jig that defines the target position is provided in the processing chamber 31, instead of locating the substrate W, and teaching is performed by pressing the holding part 16 against the jig. However, such methods require an operation performed in a state where the processing chamber 31 is opened, so that particles may enter and remain in the processing chamber 31. Further, in order to allow an operator to perform an operation, a cooling operation in the processing chamber 31 is required, which increases a non-operating time (idle time) of the substrate processing apparatus 1 even though the cooling operation is not required except during maintenance. Further, the teaching performed under room temperature after the cooling does not include the effects of thermal expansion of the placing table 32 and the lift pins 38, so that it is difficult to perform high-precision teaching. In consideration of the above issues, the inventors of the present disclosure have developed a teaching method that does not require an operation of opening the processing chamber 31 and can be performed without cooling the placing table 32.

Referring back to the description of the configuration of the substrate processing apparatus 1, as shown in FIG. 4, the controller 5 is connected to the position detection part 4, the driving controller 15, the pulse encoder 17, and the lift mechanism 39, and cooperates therewith to perform operations from the operation of identifying the target position to the teaching operation. Further, the controller 5 is a computer including a center position identifying part 51 for calculating the center P of the placing surface 33, a program storage part 52 for storing various programs for operating individual components of the substrate processing apparatus 1, a central processing unit (CPU) 53, and a memory 54. The program for transferring the wafer is configured such that the holding part 16 holds the substrate W and transfers the substrate W to each of the set positions of the film forming modules 101 to 104 as a destination. Specifically, the program has a group of steps for calculating the trajectory of the holding part 16. Further, the program for identifying the transfer target position of the holding part 16 has a plurality of groups of steps for performing various processes to be described later.

Various programs are installed in the program storage part 52 via a storage medium such as a USB memory or a DVD-ROM. The controller 5 manages the operation control of the transfer mechanism 10 by the driving controller 15 such that the holding part 16 moves based on a recipe constituting the processing program for the substrate W based on a signal from the pulse encoder 17. In the substrate processing apparatus 1 described above, the controller 5, the transfer mechanism 10, the driving controller 15, and the pulse encoder 17 constitute the substrate transfer apparatus of the present disclosure, in which teaching is performed based on the result of identifying the transfer target position.

In the case of identifying/specifying the transfer target position, the set positions (first to third positions to be described later) shown in FIGS. 7A to 7C are sequentially changed. Then, the relative positional relationship of each set position with respect to the placing table 32 is recognized based on the different behaviors of the substrate W until the substrate W from the holding part 16 is placed on the placing table 32 via the lift pins 38 depending on the set positions. Then, the final transfer target position is identified/specified based on the positional relationship.

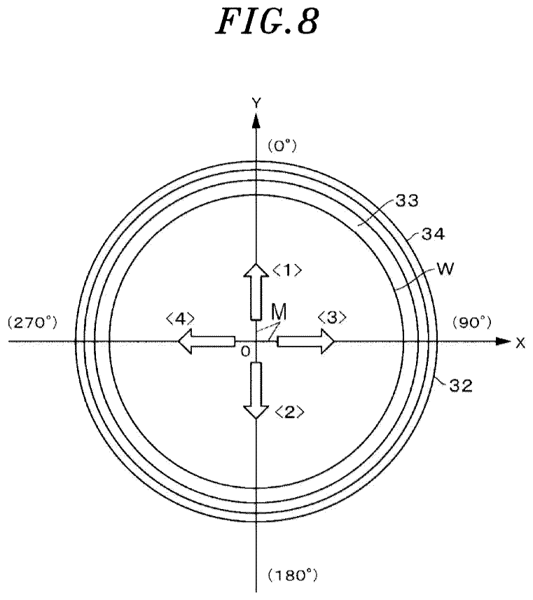

FIG. 7A shows a state after the substrate W is placed on the placing surface 33 via the lift pins 38 after the holding part 16 (not shown in FIGS. 7A to 7C) is located at the first position. Here, the first position is a position where it is assumed that the deviation between the center C of the substrate W and the center P of the placing surface 33 is smaller. If this assumption is correct, the substrate W is lowered toward the placing surface 33 on the inner side of the edge portion 34 as the lift pins 38 are lowered. In this case, even if the processing chamber 31 is maintained in a vacuum atmosphere, when the substrate W approaches the placing surface 33, the substrate W is lowered while moving horizontally like a hovercraft due to the effect of gas molecules remaining between the backside of the substrate W and the placing surface 33. The horizontal movement stops when the peripheral edge of the substrate W is brought into contact with the tapered surface 34a of the edge portion 34, and the substrate W is placed on the placing surface 33 at that position (indicated by a dashed line in FIG. 7A). Here, an example in which the substrate W moves horizontally in the negative direction of the Y axis (the 180° direction shown in the plan view of FIG. 8) is illustrated, but the direction of the horizontal movement of the substrate W is basically random. However, if the placing surface 33 is slightly inclined, the substrate W moves downward along the inclination, for example.

FIG. 7B shows a state after the substrate W is placed on the placing table 32 via the lift pins 38 after the holding part 16 is located at the second position. Here, the second position is a position where it is assumed that the deviation between the center C of the substrate W and the center P of the placing surface 33 is greater than that at the first position. In the example shown in FIG. 7B, the second position is set to a position shifted from the first position toward the positive direction of the Y axis (0° direction), where it is assumed that the periphery on the 0° side of the substrate W is located above the tapered surface 34a in plan view. If this assumption is correct, when the substrate W is lowered, the end portion on the 0° direction side described above is brought into contact with the tapered surface 34a. However, if the tapered surface 34a is formed sufficiently smooth similarly to the placing surface 33, the substrate W is lowered along the tapered surface 34a, moved horizontally in the 180° direction, for example, and then placed on the placing surface 33.

FIG. 7C shows a state after the substrate W is placed on the placing table 32 via the lift pins 38 after the holding part 16 is located at the third position. Here, the third position is a position where it is assumed that the deviation between the center C of the substrate W and the center P of the placing surface 33 is greater than that at the second position. In the example shown in FIG. 7C, the third position is set to a position that is further shifted from the second position to the positive direction of the Y axis (0° direction), where it is assumed that the periphery on the 0° side of the substrate W is located above the upper end portion 34b of the edge portion 34 in plan view. If this assumption is correct, when the substrate W is lowered, the peripheral edge on the 0° side described above is brought into contact with the upper end portion 34b of the edge portion 34 and stops while being mounted on the edge portion 34. Therefore, the substrate W is placed on the placing surface 33 without horizontal movement described in FIGS. 7A and 7B.

When the set position of the holding part 16 is changed from the first position toward the third position and the substrate W is transferred to the placing table 32, the state in which the substrate W is placed on the placing surface 33 (first and second positions) and the state in which the substrate W is mounted on the upper end portion 34b of the edge portion 34 (hereinafter, also simply referred to as “substrate W mounted on the edge portion 34”) (third position), which are different from each other, are obtained. Therefore, by slightly changing the set position from the first position toward the third position and determining whether or not horizontal movement has occurred, it is possible to identify a set position (hereinafter, also referred to as “boundary position”) at which the periphery of the substrate W held at the boundary between the tapered surface 34a and the upper end portion 34b of the edge portion 34 can be located. When the edge portion 34 is formed in an annular shape as described above, if the boundary position can be identified at least at three points of the edge portion 34, the center of the edge portion 34, i.e., the center P of the placing surface 33, can be identified. As a result, it is possible to identify a target position for determining the set position of the holding part 16 such that the center C of the substrate W is located substantially above the center P of the placing surface 33.

Whether or not horizontal movement has occurred at the time of transferring the substrate W to the placing table 32 may be determined based on the results obtained after the substrate W on the placing table 32 is lifted by raising the lift pins 38 and received on the holding part 16 again, and the deviation amount of the holding position of the substrate W is identified. In other words, it is considered that a new holding position obtained after the holding part 16 receives the substrate W is shifted by the movement distance on the placing table 32 from the holding position before the transfer operation. Therefore, the position detection part 4 (the line sensors 41 to 43) is used to identify the deviation amount of the substrate W before and after the operation of transferring the substrate W to the placing table 32 (for example, the distance between the center c of the substrate W before the placing operation and the center c′ of the substrate W after the placing operation). If the deviation amount is greater than or equal to a preset threshold value, it may be determined that the substrate W has moved horizontally and that the substrate W has been placed on the placing surface 33. If the deviation amount is less than the threshold value, it may be determined that the substrate W has not moved horizontally and that the substrate W has been mounted on the upper end portion 34b of the edge portion 34.

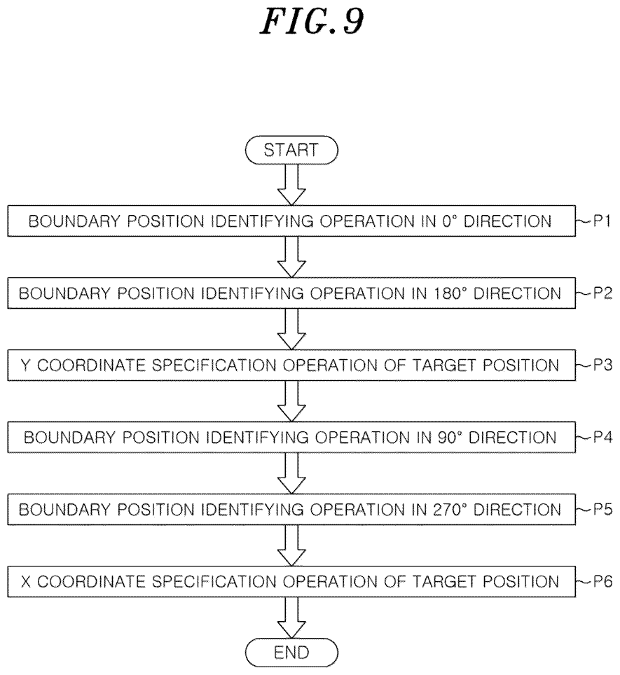

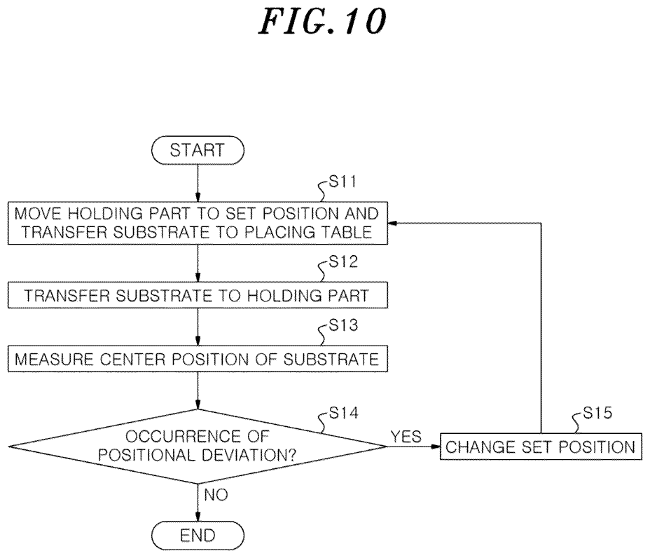

The operation of determining the target position of the holding part 16 and the teaching operation in the substrate transfer device according to the first embodiment, which are performed based on the above-described concept, will be described. FIG. 8 is a diagram showing four reference axes for identifying the boundary position (the boundary position between the tapered surface 34a and the upper end portion 34b) described above in the operation of determining a target position. In FIG. 8, the origin of the XY coordinates is located at the center of the placing surface 33, for example, and the reference axis M is set in a direction along the XY coordinates. Each reference axis is set to pass through the center side and the peripheral side of the placing surface 33 and extend in different directions at 90° intervals. In FIG. 8, the numerical values in angle brackets (< >) attached to the reference axes indicate the sequence of performing the operation for identifying the boundary position. This sequence may be selected from the reference axes and arbitrarily set. FIG. 9 is a diagram showing the procedure of the operation of determining the target position of the holding part 16.

As shown in FIGS. 8 and 9, the operation of determining the target position in the first embodiment is performed in the order of a boundary position identifying operation in the 0° direction (P1), a boundary position identifying operation in the 180° direction (P2), a Y coordinate specification operation of the target position (P3), a boundary position specification operation in the 90° direction (P4), a boundary position specification operation in the 270° direction (P5), and an X coordinate specification operation of the target position (P6), and the target position is identified based on the boundary positions. FIG. 10 is a flowchart showing a process of executing a cycle performed in the boundary position specification operation in each reference axis (hereinafter, referred to as “cycle step”). In the cycle step in the boundary position specification operation in each reference axis, the set position of the holding part 16 is moved multiple times along each reference axis as will be described later, and each operation in the cycle step shown in FIG. 10 is performed. The target position is determined based on each boundary position identified in the cycle step in each reference axis.

In the case of executing the cycle step performed in the boundary position identifying operation in the 0° direction (P1), first, the substrate W in the transfer container K transferred to the load port 21 (see FIG. 1) is transferred from the alignment chamber 26 to the load-lock chamber 23 by the transfer mechanism 25 in the atmospheric pressure transfer chamber 22. The substrate W is not limited to the substrate transferred to the transfer container K, and may be provided in the atmospheric pressure transfer chamber 22 in advance, or a dummy substrate having the same shape as the substrate W may be used.

The substrate W adjusted to be directed in a predetermined direction in the alignment chamber 26 is placed on a placing table (not shown) in the load-lock chamber 23 by the transfer mechanism 25. In the substrate W placed on the placing table in the load-lock chamber 23, the 0° peripheral edge is located at the farthest position from the gate valve 29 on the vacuum transfer chamber 24 side, for example. The load-lock chamber 23 transfers the substrate W oriented as described above to the holding part 16 of the transfer mechanism 10. The held substrate W is oriented such that the 0° peripheral edge is located on the tip end side of the holding area of the holding part 16, and the held substrate W is located at an appropriate holding position that is preset with respect to the holding part 16.

Next, the transfer mechanism 10 places the holding part 16 holding the substrate W on the measurement area A1 (see FIG. 5). The position calculation part 44 measures the position (x₁₁, y₁₁) of the center C₁₁ of the substrate W using the line sensors 41 to 43 and stores the position in the memory 54. The position (x₁₁, y₁₁) of the center C₁₁ of the substrate W located at the appropriate holding position is, e.g., (0, 0) in the relative coordinates shown in FIG. 5. Further, the position of the substrate W is identified in the alignment chamber 26, and the position (x₁₁, y₁₁) of the center C₁₁ of the substrate W before the placement on the placing table 32 substantially coincides with the appropriate holding position, so that the measurement by the position calculation part 44 may not be performed.

Hereinafter, in the boundary position identifying operation for each of the reference axes <1> to <4> shown in FIG. 8 (hereinafter, any reference axis may be referred to as “reference axis M”), the center of the substrate W before the substrate W is placed on the placing table 32 in an n^{th} cycle step may be referred to as “center c_{Mn} of the substrate W before the placing operation, and the position thereof (x_{Mn}, y_{Mn}).” Similarly to the above example, the center of the substrate W placed on the placing table 32 and then received by the holding part 16 again in the n^{th} cycle step and the position thereof may be referred to as “center c′_{Mn} of the substrate W after the placing operation, and the position thereof (x′_{Mn}, y′_{Mn}).” Further, when the direction or the number of cycle steps is not important, it may be simply referred to as “center c′(x′, y′) of the substrate W.” The above is the same in the driving system coordinates shown in FIGS. 11A to 13 to be described later. However, in the same coordinates, the center of the substrate and the position thereof before the placing operation are expressed in capital letters to be distinguished from the relative coordinate system.

Referring back to the description of the measurement of the position of the center C₁₁, the substrate W of which center C₁₁ has been measured by the position calculation part 44 is transferred to one of the film forming modules 101 to 104 for determining the target position of the holding part 16. In this example, it is transferred to the placing table 32 of the film forming module 104. When the gate valve G1 of the film forming module 104 is opened, the holding part 16 holding the substrate W is moved toward the initial setting position of the placing table 32, which will be described later, based on the substrate transfer program described above ((a) step: step of moving the transfer arm toward the set position)).

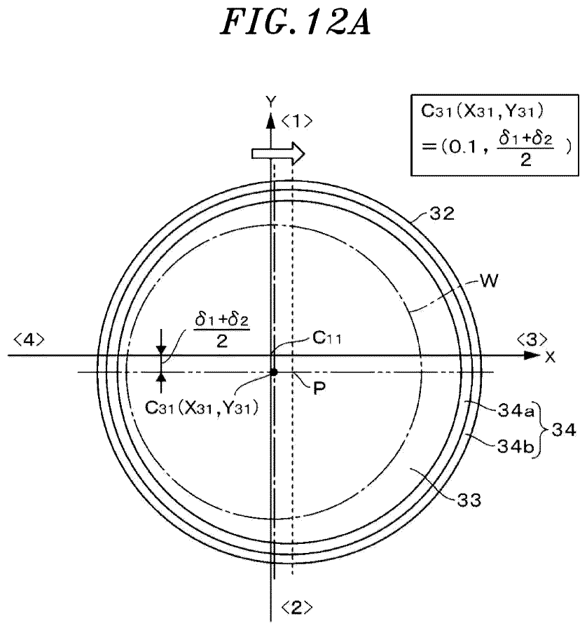

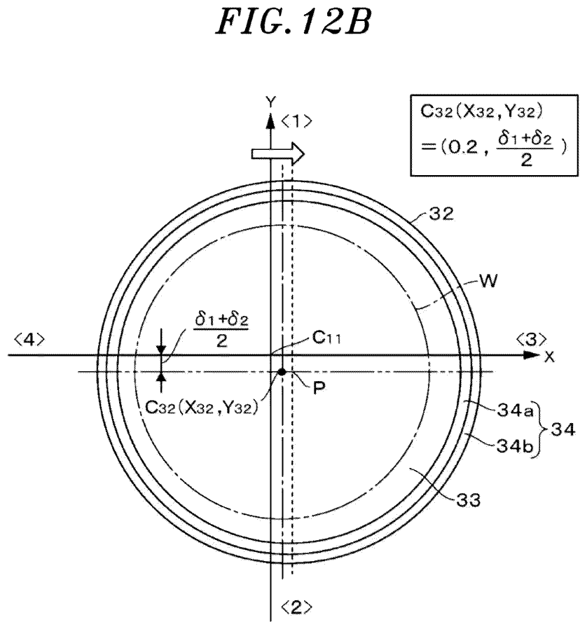

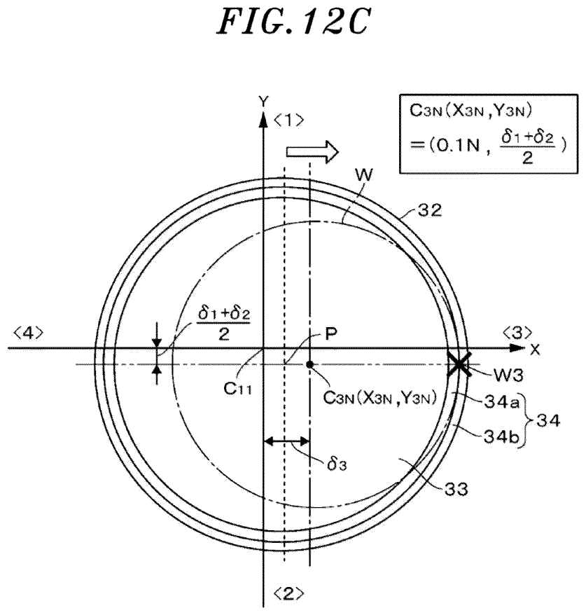

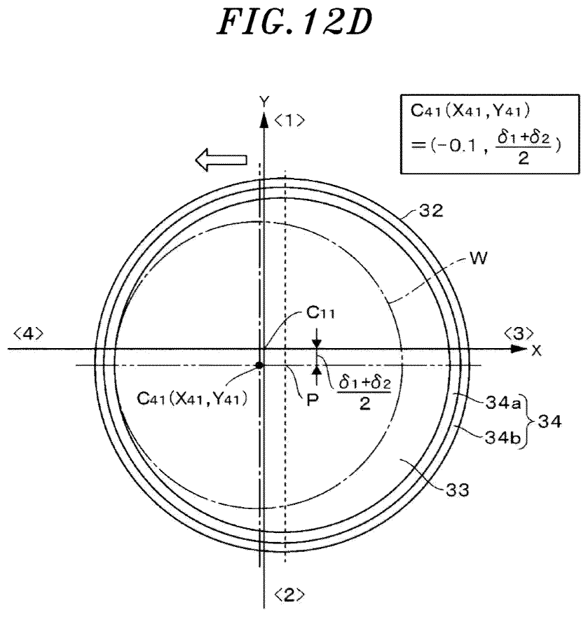

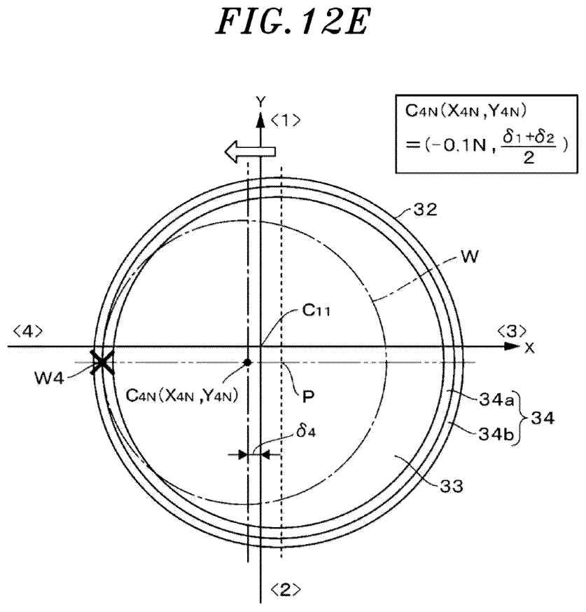

In the above example, FIGS. 11A to 11E are diagrams showing the operation of identifying the boundary position in the Y direction in plan view of the placing table 32 of the film forming module 104. FIG. 11A is a diagram showing the position of the substrate W held by the holding part 16 located at the initial setting position (hereinafter, simply referred to as “substrate W at the initial setting position”) before the substrate W is placed on the placing surface 33 in the first cycle step in the 0° direction. Similarly, FIG. 11B and FIG. 11C are diagrams showing the positions of the substrate W at the second set position and the N^{th} set position before the substrate W is placed on the placing surface 33 in the second cycle step and the N^{th} cycle step in the 0° direction, respectively. In FIGS. 11A to 11C, the illustration of the holding part 16 is omitted, the center line of the placing surface 33 is indicated by a dashed line, and the substrate W and the center line thereof are indicated by a dashed dotted line. The solid XY coordinates indicate the driving system coordinates as described above, and in order to clearly show the positional change of the substrate W, the origin is set to the position (corresponding to c(0, 0) in FIG. 5) of the center C₁₁ of the substrate W supported at the appropriate holding position of the holding part 16 at the initial setting position before the substrate W is placed on the placing table 32. The drawing specifications are the same for FIGS. 11D to 12E.

The transfer mechanism 10 transfers the substrate W from the holding part 16, which has been moved to the initial setting position shown in FIG. 11A, to the placing table 32 via the lift pins 38 (step S11, (b) step: step of transferring the substrate to the placing table). As described above, it is difficult to precisely identify the change in the center position of the placing table 32 due to maintenance or thermal expansion, or the change in the position of the substrate W transferred via the lift pins 38 in the design drawing of the substrate processing apparatus 1. Therefore, the operation of determining a target position for performing teaching is required. The initial setting position of the holding part 16 is a position that is assumed to be relatively close to the target position in the design drawing of the substrate processing apparatus 1, such as the first position described with reference to FIG. 7A.

Since, however, the initial setting position is merely a position that is assumed to be close to the target position, the center C₁₁ of the substrate W is shifted from the center P of the placing table 32 in plan view. Then, when the substrate W lowered by the lift pins 38 is placed on the placing surface 33, the substrate W moves horizontally as described above with reference to FIG. 7A and then stops on the placing surface 33.

Then, the substrate W that has stopped is transferred from the placing surface 33 to the holding part 16 via the lift pins 38 (step S12, (c) step: step of receiving the substrate by the transfer arm). In this case, the lift pins 38 protrude to raise the substrate W from the placing surface 33, and the substrate W is transferred to the holding part 16, which has been located at the initial setting position again. The transferred substrate W is held by the holding part 16 while being deviated from the appropriate holding position by the horizontal movement distance on the placing surface 33. In order to detect the deviation amount, the holding part 16 that holds the substrate W is placed in the measurement area A1, and the position c′₁₁ (x′₁₁, y′₁₁) of the center of the deviated substrate W is measured (step S13, (d) step: step of detecting a new holding position). Based on the center position c′₁₁ of the substrate W corresponding to the new holding position, the center position identifying part 51 determines whether or not the substrate W was mounted on the edge portion 34 when the substrate was transferred from the holding part 16 to the placing table 32 via the lift pins 38 (step of determining whether or not the substrate W was mounted on the edge portion 34). Whether or not the substrate W was mounted on the edge portion 34 is determined by detecting the deviation amount D from the appropriate holding position, which corresponds to the horizontal movement distance on the placing surface 33, based on the position of the center c′₁₁ of the deviated substrate W and the position of the center c₁₁ of the substrate W before the placement on the placing table 32 (step S14).

For example, the deviation amount D is calculated based on the following Eq. (1).

$$deviation amount D = {\{ {( {x}_{11}^{′} - {x}_{11} - {x}_{0} )}^{2} + {( {y}_{11}^{′} - {y}_{11} - {y}_{0} )}^{2} \}}^{1 / 2} \qquad Eq . ( 1 )$$

Here, x₀ and y₀ in Eq. (1) are correction terms for reflecting slight changes in the center position of the substrate W that occur when the substrate W is transferred from the holding part 16 to the lift pins 38 and then transferred from the lift pins 38 to the holding part 16. For example, x₀ and y₀ can be identified by transferring the substrate W, which has been supported in advance at the appropriate holding position, from the holding part 16 to the lift pins 38 and then transferring the substrate W from the lift pins 38 to the holding part 16 without placing the substrate W on the placing table 32, and using the result of measuring the center position c₀(x₀, y₀) of the substrate W by the position calculation part 44. In addition, in the case of increasing the number of cycle steps to two, three, . . . , for the boundary position identifying operation on an arbitrary reference axis M shown in FIG. 8, the deviation amount D in an arbitrary n^{th} cycle step can be expressed by the following Eq. (1)′.

$${\{ {( {x}_{Mn}^{′} - {x}_{Mn} - {x}_{0} )}^{2} + {( {y}_{Mn}^{′} - {y}_{Mn} - {y}_{0} )}^{2} \}}^{1 / 2} \qquad Eq . {( 1 )}^{′}$$

Based on the deviation amount D described above, it is determined whether or not the substrate W has been placed on the placing surface 33 and has moved horizontally, or whether or not the substrate W has mounted on the upper end portion 34b of the edge portion 34 and has not moved horizontally. They are determined based on whether or not the deviation amount D is greater than or equal to the preset threshold value as described above. The width L of the tapered surface 34a can be used as the threshold value for the determination, for example. Compared to the case where the substrate W is mounted as described with reference to FIG. 7C, when the substrate W moves horizontally until the substrate W is placed on the placing table 33 as described with reference to FIG. 7A and FIG. 7B, it is empirically understood that the movement distance is at least greater than the width L of the tapered surface 34a (see FIGS. 7A and 11A, hereinafter, also referred to as “taper width L”). Therefore, if the deviation amount D is greater than or equal to the taper width L, it is estimated that the substrate W transferred to the placing table 32 and has moved horizontally, and it is determined that the substrate W was not mounted on the upper end portion 34b of the edge portion 34. In the first cycle step of the boundary position identifying operation in the 0° direction (direction of <1> also shown in FIG. 11A) in this example, the initial setting position is the same as the first position described with reference to FIG. 7A, and the substrate W moves horizontally on the placing table 32, so that the deviation amount D becomes greater than the width L. Therefore, the center position identifying part 51 confirms the occurrence of positional deviation of the substrate W (Yes in step S14).

Next, the center position identifying part 51 changes the set position of the holding part 16 from the initial setting position to the second setting position (step S15). The second setting position is a position of the holding part 16 where the substrate W is shifted by a preset distance (for example, 0.1 mm) in the 0° direction from the position of the substrate W at the initial setting position. If it is not possible to determine that the substrate W has mounted, the set position is slightly moved along the reference axis (steps S15 to S14). Then, the cycle step of determining whether or not the substrate W has mounted based on the measured deviation amount D of the center c of the substrate W is repeated until it is confirmed that the substrate W has mounted. Accordingly, the boundary position, which is the set position when the substrate W has mounted, can be identified.

If the holding part 16 moving toward the second setting position is supporting the substrate W at the appropriate holding position, the second setting position may be displaced by 0.1 mm in the 0° direction from the initial setting position. However, in the first embodiment, the substrate W is held at a position shifted from the appropriate holding position in the first cycle step. As a first method for dealing with such a circumstance, the substrate W can be held again and set to the second set position. For example, after the position of the center c′₁₁ of the substrate W is measured in the measurement area A1, the holding part 16 is loaded into the film forming module 104 again to hold the substrate W again using the lift pins 38. Before the substrate W is returned to the original state, the holding part 16 is moved to the initial setting position, which is the previous setting position, to transfer the substrate W to the lift pins 38, and the position is corrected to shift the holding part 16 by the displacement (X′₁₁−X₁₁, Y′₁₁−Y₁₁) of the substrate W with respect to the holding part 16. Then, the substrate W is transferred from the lift pins 38 to the holding part 16 whose position has been corrected. Accordingly, the substrate W can be located at the appropriate holding position.

The first method may be performed by using the transfer mechanism 25 having an edge grip function, instead of using the film forming module 104 as described above. The position of the substrate W can be corrected by transferring the substrate W from the transfer mechanism 10 to the transfer mechanism 25, and performing positioning using the regulating protrusion 25a and the pressing part 25b of the holding portion 25m described with reference to FIG. 2. Further, when the substrate W rotates around the center on the stage and the correction of the orientation is required, the substrate W can be transferred to the alignment chamber 26 and the transfer mechanism 25 to correct the orientation and position of the substrate W.

In the second method, the substrate W can be transferred to the lift pins 38 at the second set position without being held again. In this case, in the first cycle step, the substrate W is held at a position shifted from the appropriate holding position, so that the holding portion 16 is moved to the second set position after the position is corrected in a direction in which the deviation of the substrate W is offset/cancelled based on the displacement (X′₁₁−X₁₁, Y′₁₁−Y₁₁) of the substrate W. In this case, the position where the holding part 16 supports the substrate W is shifted from the appropriate holding position described above. Since, however, the substrate W can be placed at a desired position, it is possible to perform the same transfer operation as the transfer operation performed to transfer the substrate W to the “preset holding position” in the claims.

Here, the correspondence between the relative coordinates (see FIG. 5) identified using the line sensors 41 to 43 and the coordinates shown in FIGS. 11A to 13 will be described. As described above, at the appropriate holding position, the substrate W is held by the holding part 16 such that the center c of the substrate W coincides with the origin (0,0) of the relative coordinates identified by the measurement using the line sensors 41 to 43 shown in FIG. 5 (expressed as “c(0,0)” in FIG. 5). In the first cycle step, the initial setting position is set such that the center (c(0,0) in the relative coordinate system of FIG. 5) of the substrate W coincides with the coordinates C₁₁(X₁₁, Y₁₁) shown in FIG. 11A. In the second cycle step and subsequent operations to be described later, the set position is moved slightly based on the state in which the substrate W is held at the appropriate holding position shown in FIG. 5.

In this case, when the substrate W is returned to the original state by the first method described above, the substrate W is actually held at the appropriate holding position shown in FIG. 5. Therefore, the second set position may be set such that c(0,0) identified in the relative coordinate system of FIG. 5 coincides with C₁₂, C₁₃, . . . , C_{1N}, which will be described later. Even when the substrate W is not returned to the original state by the second method, the position where the origin (0,0) of the relative coordinate system of FIG. 5 coincides with the center c of the substrate W can be identified by calculation. Therefore, the second set position may be set such that the center c(0,0) of the substrate W identified by calculation coincides with C₁₂, C₁₃, . . . , C_{1N}, which will be described later. The above-described “position correction in a direction in which the deviation of the substrate Wis offset” includes the above calculation. If there is concern about the positional deviation of the substrate W during the transfer process, the center position c(x, y) of the substrate W may be measured before the substrate W is placed on the placing table 32 in each cycle step, and the substrate W may be returned to the original state or the position correction using calculation may be performed such that the deviation can be offset. Hereinafter, the description will be made on the assumption that the substrate W is returned to the original state by the first method.

Next, as shown in FIG. 11B, the substrate W is placed at the second set position before the second cycle step. If the set position is shifted by 0.1 mm as described above, the center position of the substrate W at the second set position becomes: C₁₂(X₁₂, Y₁₂)=(X₁₁, Y₁₁+0.1). The center position identifying part 51 stores the center position C₁₂(X₁₂, Y₁₂) of the substrate W before the placing operation in the memory 54.

Thereafter, the second cycle step is performed in the same manner as the first cycle step. However, the holding part 16 is moved to the second set position to receive the substrate W via the lift pins 38 after the placing operation. Accordingly, the substrate W can be held in a position where the deviation amount from the holding position can be detected, similarly to the first cycle step. By locating the holding part 16 in the measurement area A1 after the substrate W is received, the center position c′₁₂(x′₁₂, y′₁₂) is measured. Further, the deviation amount D, which is ((x′₁₂−0−x₀)²+(y′₁₂−0−y₀)²)^{1/2}, is calculated together with the center position c(0,0) described above, and compared with the threshold value L to determine that the substrate is not mounted.

The cycle steps in the boundary position identifying operation in the 0° direction are repeated until the deviation amount D becomes less than the threshold value L. If the number of cycle step performed last is N, the N^{th} cycle step is performed in the same manner as the first cycle step described above. The center position identifying part 51 determines that the substrate W is not mounted in the N−1^{th} cycle step (Yes in step S14), and changes the set position from the N−1^{th} set position to the N^{th} set position (step S15). The N^{th} set position is the position of the holding part 16 that can be shifted by 0.1 mm in the 0° direction from the position of the substrate W at the N−1^{th} set position, and is set in the same manner as the second set position. As shown in FIG. 11C, before the placing operation of the N^{th} cycle step, the center position identifying part 51 identifies the position of the center of the substrate W at the N^{th} set position as C_{1N}(X_{1N}, Y_{1N})=(X₁₁, Y_{1(N-1)}+0.1)=(X₁₁, Y₁₁+0.1(N−1)), and stores the position of the center C_{1N} in the memory 54.

In the N^{th} cycle step, first, the transfer mechanism 10 moves the holding part 16 toward the N^{th} set position, and the substrate W is transferred from the holding part 16 located at the N^{th} set position to the placing table 32 via the lift pins 38 (step S11). Accordingly, the substrate W located at the position that has moved by 0.1 mm in the 0° direction from the position of the substrate W held by the holding part 16 at the N−1^{th} set position is lowered toward the placing table 32. In this case, an end portion W1 of the substrate W on the 0° direction side is located on the upper end portion 34b. In FIG. 11C, the substrate W is illustrated smaller than the placing table 32 for convenience of illustration, so that the end portion W1 on the 0° side is illustrated slightly shifted to the negative side of the X direction. Then, the substrate W vertically lowered by the lift pins 38 is placed on the placing table 32 in a state where the end portion W1 on the 0° side is mounted on the upper end portion 34b of the edge portion 34 (see FIG. 7C). Therefore, the substrate W placed on the placing table 32 does not move horizontally on the placing table 32.

The substrate W mounted on the edge portion 34 is raised by the lift pins 38, and transferred to the holding part 16 at the N^{th} set position in the case of returning the substrate W to the original state, similarly to the second cycle step (step S12). The substrate W transferred to the holding part 16 at the N^{th} set position does not move horizontally on the placing surface 33, and thus is hardly shifted from the holding position before the placing operation. Similarly to the second cycle step, the holding part 16 that has moved to the N^{th} set position holds the substrate W, and moves to the measurement area A1 to measure the position c′_{1N}(x′_{1N}, y′_{1N}) of the center of the substrate W (step S13). The center position identifying part 51 detects the deviation amount D from the positions of the centers (c_{1N}, c′_{1N}) before and after the N^{th} cycle step.

The deviation amount D of the N^{th} cycle step is obtained as ((x′_{1N}−0−x₀)²+(y′_{1N}−0−y₀)²)^{1/2} from the above Eq. The positions of the centers (c_{1N}, c′_{1N}) of the substrate W before and after the N^{th} cycle step are close to c(0,0) shown in FIG. 5, and the deviation amount D is very small and less than the width L of the tapered surface 34a. Therefore, the center position identifying part 51 determines that the substrate W was mounted on the upper end portion 34b when the substrate W was transferred to the placing table 32 in the N^{th} cycle step (No in step S14, step of determining whether or not the substrate was mounted on the edge portion). Then, the N^{th} set position is identified as the boundary position. It is not necessarily determined that the substrate W is mounted when the deviation amount D is less than the threshold value L (D<L), but it may be determined that the substrate W is mounted when the deviation amount D is less than or equal to than the threshold value (D≤L). Then, the center position identifying part 51 calculates a displacement amount δ1 of the position of the substrate W before the placing operation at the N^{th} set position with respect to the position of the substrate W before the placing operation at the initial setting position, and stores it in the memory 54. The displacement amount δ1 is (N−1)×0.1 mm (positive value) in the Y direction. In this manner, the operation of identifying the boundary position in the 0° direction is completed.

Next, similarly to the above-described boundary position identifying operation in the 0° direction (P1), the boundary position identifying operation in the 180° direction (P2) (the direction of <2> also shown in FIGS. 11D and 11E) is repeated until the N^{th} cycle step for determining whether or not the substrate W is mounted. FIGS. 11D and 11E are diagrams showing the positions of the substrate W in the first and N^{th} set positions before the first and N^{th} cycle steps in the 180° direction. In the identifying operation in the 180° direction (P2), the first set position in the first cycle step is set such that the substrate W can be shifted by 0.1 mm in the 180° direction from the center C₁₁ of the substrate W in the initial setting position described in the first cycle step in the 0° direction (see FIG. 11D). If the deviation of the substrate W from the holding position in the holding part 16 after the placing operation in the previous N^{th} cycle step in the 0° direction cannot be ignored, the substrate W may be returned to the original state and then moved to the first set position as described above.

As shown in FIG. 11D, before the placing operation in the first cycle step in the 180° direction, the position of the center of the substrate W at the first set position becomes: C₂₁(X₂₁, Y₂₁)=(X₁₁, Y₁₁−0.1). Then, as shown in FIG. 11E, in the N^{th} cycle step in the 180° direction, the position of the center of the substrate W at the N^{th} set position before the placing operation becomes: C_{2N}(X_{2N}, Y_{2N})=(X₁₁, Y_{2(N-1})−0.1)=(X₁₁, Y₁₁−0.1N). In this case, an end portion W2 of the substrate W transferred to the placing table 32 on the 180° direction side is located on the upper end portion 34b, and the end portion W1 of the substrate W vertically lowered by the lift pins 38 on the 180° direction side is mounted on the upper end portion 34b and does not move horizontally on the placing table 32 (see FIG. 7C).

The substrate W mounted on the edge portion 34 is transferred to the holding part 16 at the N^{th} set position in the case of returning the substrate W to the original state (step S12). In this case, the transferred substrate W is hardly shifted from the holding position before the placing operation. Then, the position c′_{2N}(x′_{2N}, y′_{2N}) of the center of the substrate W is measured (step S13). The center position identifying part 51 detects the deviation amount D from the positions of the centers (c_{2N}, c′_{2N}) of the substrate W before and after the N^{th} cycle step.

The deviation amount D becomes smaller than the width L of the tapered surface 34a, and the center position identifying part 51 determines that the substrate W was mounted in the N^{th} cycle step (No in step S14) and identifies the N^{th} set position as the boundary position in the 180° direction. Then, the center position identifying part 51 calculates and stores a displacement amount δ2 of the substrate W at the N^{th} set position before the placing operation with respect to the position of the substrate W at the initial setting position. The displacement amount δ2 is −0.1 N (negative value) mm in the Y direction. Accordingly, the operation of identifying the boundary position in the 180° direction (P2) is completed.

Next, an operation of identifying the Y coordinate of the target position (P3) is performed. Here, the Y coordinate of the center P of the placing surface 33 is determined based on the initial setting position in the 0° direction. If the placing surface 33 has a circular planar shape and the edge portion 34 is formed along the outer periphery of the placing surface 33, the center position of the placing surface 33 coincides with the intermediate position of the inner periphery of the upper end portion 34b identified in the previous identifying operations (P1 and P2). From the above, the Y coordinate value Yp of the center P of the placing surface 33 is obtained by correcting the Y coordinate value of the center position (C₁₁(X₁₁, Y₁₁)) of the substrate W at the initial setting position by the correction value “+(δ1+δ2)/2” calculated from the displacement amounts δ1 and δ2 described above. Therefore, it was possible to identify the Y coordinate position of the center P of the placing surface 33 corresponding to the substrate transfer target position where the substrate W can be transferred to the center P of the placing surface 33. Accordingly, in the following identifying operation, the Y coordinate of each set position is set to be aligned with the Y coordinate of the center P of the placing surface 33.

Next, the boundary position identifying operations (in the 90° direction (direction <3> also shown in FIGS. 12A to 12C) and the 270° direction (direction <4> also shown in FIG. 12D) (P4 and P5) are performed in the same manner as the boundary position identifying operation in the 180° direction (P2). FIGS. 11A to 12E are diagrams showing the boundary position identifying operation in the X direction in the first embodiment. In FIGS. 11A to 12E, the dashed double-dotted line indicates the common center line in the X direction of the substrate W and the placing table 32. In the operation of identifying the boundary position in the X direction, the set position is moved slightly along the center line. FIGS. 12A, 12B, and 12C are diagrams showing the positions of the substrate W at the first, second, and N^{th} set positions in the first, second, and N^{th} cycle steps in the 90° direction.

For the first set position in the first cycle step in the identifying operation (P4), the X coordinate of the initial setting position is shifted by +0.1 mm in the 90° direction, and the target Y coordinate position is set such that the Y coordinate is aligned with the center P of the placing surface 33. In consideration of the target Y coordinate position, the position of the center of the substrate W before the placing operation at the first set position becomes: C₃₁(X₃₁, Y₃₁)=(X₁₁+0.1, Y₁₁+(δ1+δ2)/2)=(0.1,(δ1+δ2)/2) (see FIG. 12A).

The second set position is the position where the substrate W can be located while being shifted by 0.1 mm in the 90° direction from the position of the substrate W before the placing operation at the first set position. As a result, as shown in FIG. 12B, the position of the center of the substrate W at the second set position before the placing operation in the second cycle step becomes: C₃₂(X₃₂, Y₃₂)=(X₃₁+0.1, Y₃₁)=(0.2, (δ1+δ2)/2).

Further, as shown in FIG. 12C, the position of the center of the substrate W before the placing operation at the N^{th} set position becomes: C_{3N} (X_{3N}, Y_{3N})=(X3_{(N-1)}+0.1, Y₃₁)=(0.1N, (δ1+δ2)/2). Further, at the N^{th} set position, an end portion W3 of the substrate W on the 90° side is located on the upper end portion 34b. When the substrate W is placed on the placing table 32, the end portion W3 of the substrate W on the 90° side is mounted on the upper end portion 34b and does not move horizontally on the placing table 32 (see FIG. 7C). Thereafter, it is determined that the substrate W was mounted based on the result of the calculation of the deviation amount D described above, and the operation of identifying the boundary position in the 90° direction (P4) is completed. The displacement amount δ3 of the position of the substrate W before the placing operation at the N^{th} set position with respect to the position of the substrate W before the placing operation at the initial setting position is 0.1 Nmm (positive value) in the X direction.

FIGS. 12D and 12E are diagrams showing the positions of the substrate W at the first and N^{th} set positions before the placing operation in the first and N^{th} cycle steps in the 270° direction. The first set position of the first cycle step in the identifying operation of the boundary position in the 270° direction (P5) is set such that the X coordinate of the initial setting position is shifted by −0.1 mm in the 270° direction, and the Y coordinate is aligned with the Y coordinate of the center P of the placing surface 33. In other words, the position of the center of the substrate W at the first set position becomes: C₄₁(X₄₁, Y₄₁)=(X₁₁−0.1, Y₁₁+(δ1+δ2)/2)=(−0.1, (δ1+δ2)/2) (see FIG. 12D).

As shown in FIG. 12E, the position of the center of the substrate W before the placing operation at the N^{th} set position becomes: C_{4N}(X_{4N}, Y_{4N})=(X_{4(N-1)}−0.1, Y₄₁)=(−0.1N, (δ1+δ2)/2). Further, at the N^{th} set position, an end portion W4 of the substrate W on the 270° side is located on the upper end portion 34b. When the substrate W is placed on the placing table 32, the end portion W4 of the substrate W on the 270° side is mounted on the upper end portion 34b and does not move horizontally on the placing table 32 (see FIG. 7C). Then, it is determined that the substrate W was mounted based on the result of the calculation of the deviation amount D described above, and the operation of identifying the boundary position in the 270° direction (P5) is completed. Similarly to the displacement amount δ3 in the 90° direction described above, the displacement amount δ4 of the substrate W in the X direction in the identifying operation of the boundary position in the 270° direction is −0.1 Nmm (negative value).

Next, an X-coordinate identifying operation (P6) is performed, similarly to the Y-coordinate identifying operation (P3) of the target position. The X-coordinate position Xp of the center P of the placing surface 33 is obtained by correcting the X-coordinate value of the center position (C₁₁(X₁₁, Y₁₁)) of the substrate W at the initial setting position by the correction value “+(δ3+δ4)/2” obtained from the displacement amounts δ3 and δ4 described above. Therefore, it is also possible to identify the X-coordinate position of the center P of the placing surface 33 corresponding to the substrate transfer target position where the substrate W can be transferred to the center P of the placing surface 33. Hence, in the first embodiment, the target position is determined such that the center of the substrate W held at the holding position coincides with the position (Xp, Yp) of the center P of the placing surface 33 identified in the target position coordinate identifying operations P3 and P6 (step of determining target position). The center position identifying part 51 sets the target position as the set position of the holding part 16 using the driving controller 15 that is the driving control part (step of setting target position). As a result, the target position of the film forming module 104 is taught to the driving controller 15.

The operation of determining a target position and the teaching operation are also performed for the film forming modules 101 to 103 other than the film forming module 104. As described above, the operation of determining a target position and the teaching operation are performed during a period in which the substrate is not processed, such as the film forming process or the like. After the operation of determining a target position and the teaching operation for the film forming modules 101 to 104 are completed, the film forming process is started in the substrate processing apparatus 1. In the first embodiment, the substrate W is transferred in the following order during the film forming process in the substrate processing apparatus 1: the transfer container K→the load port 21→the alignment chamber 26→the atmospheric pressure transfer chamber 22→the vacuum transfer chamber 24→any one of the film forming modules 101 to 104. The substrate W subjected to the film forming process in any of the film forming modules 101 to 104 is transferred in the reverse order and returned to the transfer container K.

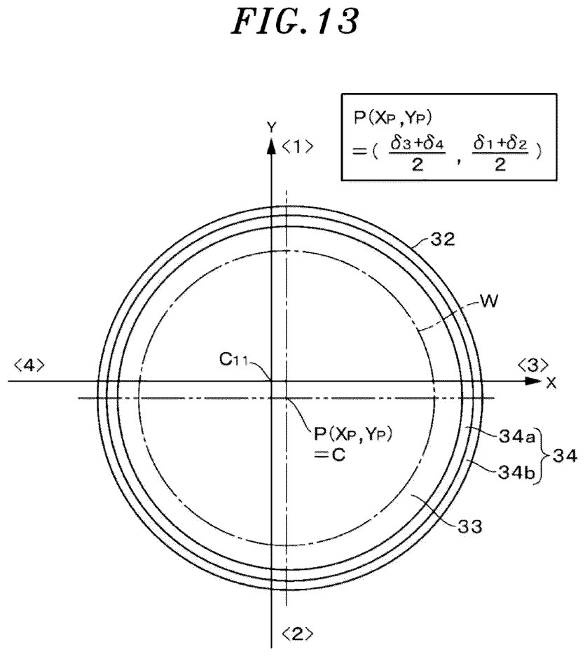

In the case of transferring the substrate W to any of the film forming modules 101 to 104 on the transfer path, the holding part 16 holding the substrate W is moved to a set position taught by the driving controller 15 as shown in FIG. 13. The substrate W supported by the holding part 16 is located on the center P of the placing surface 33, lowered toward the center P of the placing surface 33 via the lift pins 38, and moved horizontally on the placing surface 33. Then, the substrate W stops on the placing surface 33, and is placed on the placing surface 33. Next, the film forming process is performed on the substrate W.

In accordance with the teaching method for the transfer device of the first embodiment, when the transfer arm 10a transfers the substrate W to the film forming modules 101 to 104, the set position of the holding part 16 can be set based on the target position that has been determined in advance by the operation of determining the target position in the first embodiment. According to the determination of the target position in the first embodiment, the holding part 16 is located at a temporary set position in a plurality of preset reference axes, and the substrate W is transferred to the placing table 32. Then, the positions of the center c of the substrate W before and after the transfer operation are measured by the line sensors 41 to 43. Then, the cycle step is repeated in each reference axis while changing the set position until the deviation amount D of the substrate W before and after the transfer operation becomes less than the threshold value and it is determined that the substrate W is mounted on the edge portion 34. Then, the position of the center P of the placing surface 33 is identified based on one set position in each reference axis, which is obtained when it is determined that the substrate W is mounted on the edge portion 34. The target position of the holding part 16 is determined from the position of the center P of the placing surface 33 identified as described above, and the set position of the holding part 16 is taught by setting the target position as the set position. By setting the set position as described above, the substrate W can be transferred onto the center P of the placing surface 33 and reliably placed on the placing surface 33.

### Modification of First Embodiment

As shown in the first embodiment, it is preferable to obtain the position of the center P of the placing surface 33 and set the target position where the center C of the substrate W is located at the position of the center P as the set position, but this is not necessary. For example, if the substrate can be reliably placed on the placing surface 33, the target position may be determined as the vicinity of the center P of the placing surface 33. In the first embodiment, the position of the center P of the placing surface 33 is obtained. However, the present disclosure is not limited thereto, and the target position may be determined without obtaining the center P (Xp, Yp). In this case, the target position may be arbitrarily determined such that the center C of the substrate W is located in the inner area of the centers C_{1N}, C_{2N}, C_{3N}, and C_{4N} of the substrate W at the boundary position of the respective reference axes.

In the first embodiment, the boundary position is identified using four reference axes. However, the boundary position may be identified using three reference axes. Further, the boundary position may be identified using two reference axes. Specifically, for example, when the placing table 32 is provided in advance at a position where the transfer arm 10a is fully extended, the Y coordinate of the target position has been determined in advance, so that the boundary position may be identified using only two reference axes, such as 90° and 270°.

In the first embodiment, the set position is moved slightly by 0.1 mm. However, the movement distance can be set arbitrarily. For example, it is preferable to set the movement distance such that the measurement error expected in the case of identifying the boundary position from the diameter difference between the placing surface 33 and the substrate W are within a tolerable range. If the movement distance is set to be long, the measurement error become relatively large. If the movement distance is set to be short, the measurement error become relatively small, whereas the number of cycle steps increases and the required time increases. Further, the movement distance may not be constant and may vary as in the first embodiment. In this case, the movement distance may be set to be long, e.g., 0.5 mm, when the substrate W moves toward the initial setting position in each reference axis, and may be set to be short, e.g., 0.1 mm, in several cycle steps. If it is suddenly determined that the substrate W is mounted when the movement distance is long, the substrate W may be moved in the opposite direction by a short movement distance, e.g., 0.1 mm, to find a case where it is determined that the substrate W is not mounted, and the setting position immediately before the case where the substrate W is determined to be mounted may be determined as the boundary position. As described above, the movement of each setting position can be performed in various manners.

In the first embodiment, the position and trajectory of the holding part 16 are set for the holding area, and the center of the holding area and the center C of the substrate W at the holding position are set to be aligned. However, it is not necessary that they are set to be aligned. The teaching method in the first embodiment is performed for the setting positions of the film forming modules 101 to 104, but the present disclosure is not limited thereto. For example, the teaching method can also be used for the setting positions of the placing tables in the load-lock chamber 23, and for a spin chuck in a liquid processing module that is not disclosed in the present disclosure.

In the first embodiment, the lift pins 38 are raised with respect to the placing surface 33 whose height is fixed, thereby transferring the substrate W to and from the holding part 16. However, the present disclosure is not limited thereto. For example, the height of the tip ends of the lift pins 38 may be fixed, and the placing table 32 may be configured to be raised and lowered vertically. In this case, when the substrate W transferred to the holding part 16 is placed on the placing table 32, first, the placing table 32 is lowered in advance to a position lower than the lift pins 38, so that the lift pins 38 protrude from the placing surface 33. Thereafter, the holding part 16 located at a set position is lowered to transfer the substrate W to the lift pins 38. Then, the holding part 16 retracts from the processing chamber 31, and the placing table 32 is raised to a position higher than the lift pins 38, so that the substrate W is placed on the placing table 32. By performing the above operation in the reverse order, the substrate W placed on the placing table 32 can be transferred to the holding part 16.

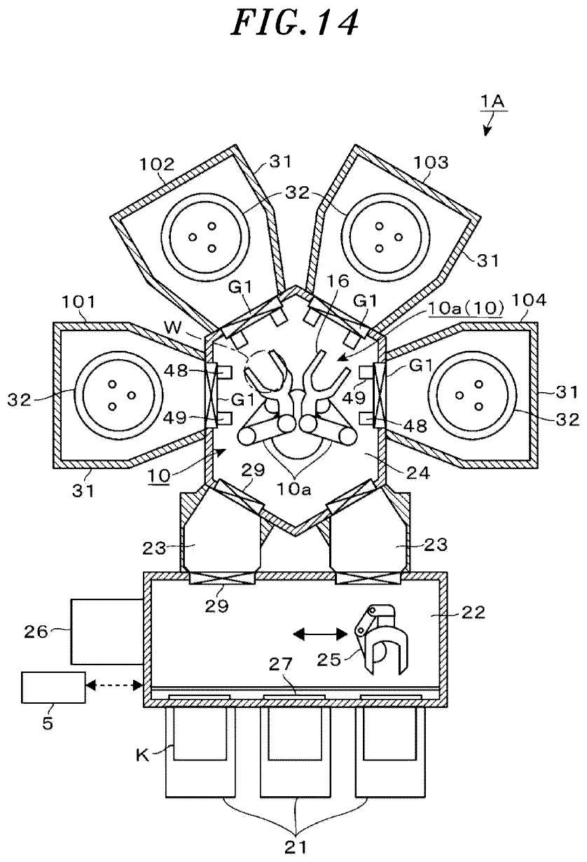

The present disclosure is not limited to the case of measuring the positional deviation of the substrate W before and after the placing operation using the line sensors 41 to 43 as in the substrate processing apparatus 1 of the present disclosure. FIG. 14 is a plan view showing a modification of the substrate processing apparatus 1. In a substrate processing apparatus 1A, line sensors 48 and 49 of which arrangement and number are different from those of the line sensors 41 to 43 of the first embodiment are provided in the vacuum transfer chamber 24. Similarly to the line sensors 41 to 43, the line sensors 48 and 49 are provided in the housing of the vacuum transfer chamber 24, and arranged on both sides of the gate valve G1 in front of the gate valves G1 of the film forming modules 101 to 104. Since the light is blocked by the 90° side and 270° side portions of the substrate W that is linearly loaded into and unloaded from the film forming modules 101 to 104, the line sensors 48 and 49 can measure the position of the center c of the substrate W that has passed therethrough by detecting four peripheral points of the substrate W.

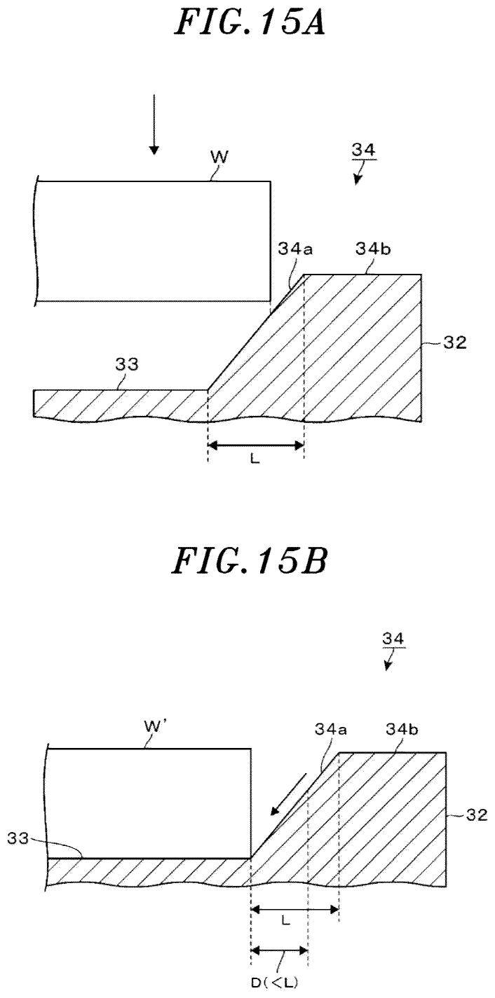

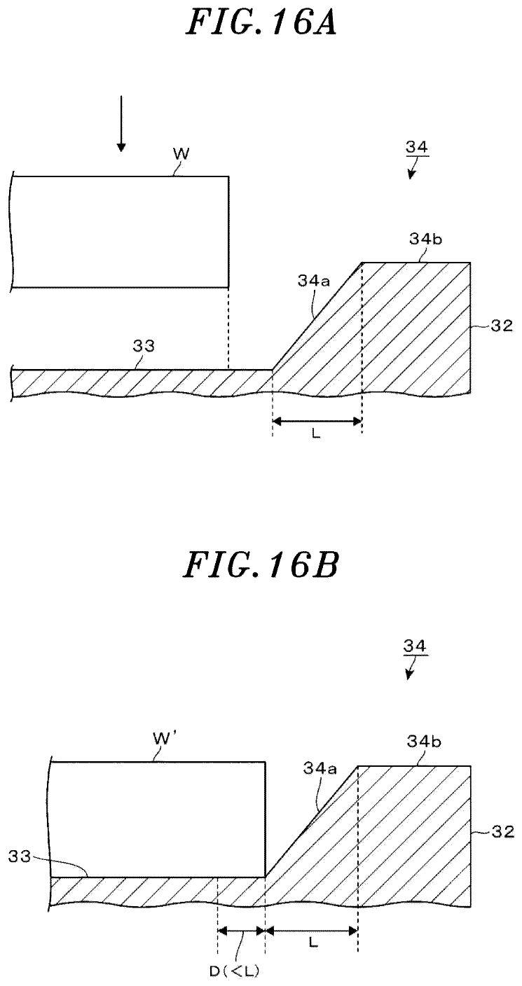

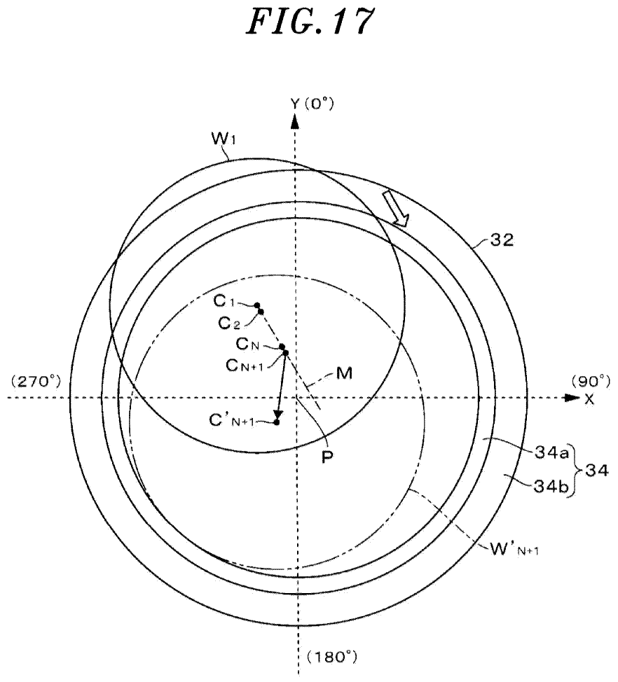

In the first embodiment, the substrate W is transferred by the transfer arm 10a that is a multi-joint arm. However, the substrate W may be transferred by another transfer mechanism, such as a transfer mechanism that moves by magnetic levitation using electromagnets. Although the edge portion 34 in the first embodiment has the tapered surface 34a, the tapered surface 34a may not be provided, and the inner peripheral side of the edge portion 34 may be a surface standing upright from the placing table 32. In this case, the threshold value for the deviation amount can be appropriately set to a very small value that can be used for determining whether or not the substrate W is mounted. Further, the taper width L is used as the threshold value for the deviation amount D, but this is not necessary. For example, whether or not the substrate W is mounted may be determined based on a determination criterion other than the taper width L depending on circumstances such as the weight of the substrate W, the shape of the placing table 32 such as the inclination of the placing surface 33, or the surface roughness or the degree of inclination of the tapered surface 34a, and the positional deviation at the time of transfer with the holding part 16 and the lift pins 38. The case of erroneously determining whether or not the substrate W is mounted based on the taper width L will be described with reference to FIGS. 15 and 16.

FIGS. 15 and 16 are diagrams showing an example in which the deviation amount D may be less than the taper width L, which is the threshold value, even when the substrate W is not mounted. The arrows shown in FIGS. 15 and 16 indicate the direction of movement of the substrate W. Similarly to the example described with reference to FIGS. 7A to 7C, the placing table 32 shown in FIGS. 15 and 16 has the tapered surface 34a that is lowered from the periphery toward the center on the inner peripheral side of the edge portion 34. Although not shown in FIGS. 15 and 16, the placing surface 33 of the placing table 32 is formed as an inclined surface in which the height position of the placing surface 33 becomes lower from the center toward the periphery where the edge portion 34 in each drawing is provided.

In this case, the substrate W may be transferred to the placing table 32 from a set position in which the peripheral edge of the substrate W is located above the tapered surface 34a, as shown in FIG. 15A, for example. At this time, as shown in FIG. 15B, when the peripheral edge of the substrate W is brought into contact with the tapered surface 34a, the substrate W slides down toward the placing surface 33 in a state where the peripheral edge position thereof is restricted by the tapered surface 34a. If the height position of the placing surface 33 is inclined to become lower toward the edge portion 34 as described above, the substrate W that has reached the placing surface 33 may stop near the lower end position of the tapered surface 34a without hardly moving in the horizontal direction. Hereinafter, the substrate W that has placed on the placing table 32 and has stopped will be referred to as “substrate W′.” In this case, even though the substrate W′ is not mounted on the edge portion 34, the deviation amount D is less than the taper width L. Therefore, in accordance with the method of the first embodiment described above, it is erroneously determined that the substrate W′ is mounted on the edge portion 34.

For another example, FIG. 16A shows a case where the distance from the peripheral edge of the substrate W to the inner periphery of the tapered surface 34a is shorter than the width L of the tapered surface 34a when the set position is moved from the center toward the periphery of the placing surface 33 along the reference axis. In this case, the substrate W placed on the placing surface 33 moves slightly toward the tapered surface 34a due to the inclined surface of the placing surface 33, and stops near the tapered surface 34a (see FIG. 16B). In this case, the substrate W′ is not mounted, but it is erroneously determined that the substrate W′ is mounted by the method of the first embodiment because the deviation amount D is less than the taper width L. As described in the above two examples, even if the set position is further changed toward the peripheral side of the placing surface 33 along the reference axis, erroneous determination in which the correct boundary position cannot be identified may occur. The boundary position identifying operation of the second embodiment, which can prevent occurrence of erroneous determination, will be described with reference to FIG. 17.

### Second Embodiment

FIG. 17 is a diagram showing an example of a boundary position identifying operation on one reference axis M in the second embodiment. As indicated by the dashed line in FIG. 17, in this example, a reference axis M that crosses the second quadrant diagonally is set with respect to the XY coordinates passing through the center of the placing table 32. A part of the substrate position in the identifying operation from the first cycle step to the N+1^{th} cycle step in the identifying operation is shown. In FIG. 17, in an arbitrary n^{th} cycle step, a substrate Wn (indicated by solid line) located at a set position and the center Cn thereof in the corresponding cycle, and a substrate W′n (indicated by dashed double-dotted line) that has stopped after the substrate Wn is placed on the placing table 32 and the center C′n thereof are illustrated.

In the boundary position identifying operation in the second embodiment, the first set position in the first cycle step is set such that the peripheral portion of the substrate W located at the first set position is mounted on the edge portion 34. Further, in each cycle step, the set position is moved from the periphery toward the center of the placing surface 33 along the reference axis M based on the preset movement distance. Accordingly, the center position of the substrate W at each set position is displaced as C₁, C₂, . . . . C_{N}, C_{N+1} along the reference axis M from the periphery toward the center of the placing surface 33.

In the example shown in FIG. 17, it is assumed that the substrate W′ after the placing operation is mounted on the edge portion 34 from the first to the N^{th} cycle steps. Then, in the N+1^{th} cycle, it is assumed that the peripheral edge of the substrate W reaches the tapered surface 34a of the edge portion 34, and the substrate W slides down along the tapered surface 34a toward the placing surface 33. In this case, the substrate W hardly moves in the first to N^{th} cycle steps, so that the deviation amount D is very small and less than the threshold value L to be described later. Accordingly, it is determined that the substrate W is mounted. In the N+1^{th} cycle step, the substrate W of which center C_{N+1} is located at the N+1^{th} set position is not mounted on the edge portion 34, and moves horizontally on the placing surface 33. Since the deviation amount D exceeds the threshold value, it is not determined that the substrate W is mounted. The center position identifying part 51 repeats the cycle up to the N+1^{th} cycle, and identifies the set position of the N^{th} cycle, in which it is determined last that the substrate W is mounted, as the boundary position. In accordance with the second embodiment in which the set position is changed from the periphery to the center of the placing table 32 along the reference axis M, as shown in FIG. 16, it is possible to prevent the cycle step from being executed at a position where the distance from the periphery of the substrate W to the inner circumference of the tapered surface 34a is less than the taper width L. As a result, it is possible to prevent the occurrence of erroneous determination described with reference to FIG. 16.

In order to prevent the case in which it is erroneously determined that the substrate W is mounted from occurring when a position where the peripheral edge of the substrate W is located above the tapered surface 34a is set as a set position as shown in FIG. 15, it is preferable to avoid using the width L of the tapered surface 34a as the threshold value. When the set position is moved from the first set position where the substrate W is mounted on the edge portion 34 toward the center as in the second embodiment described with reference to FIG. 17, the threshold value is set to be less than the width L of the tapered surface 34a, for example. For example, the threshold value is set to a value obtained by subtracting the movement distance of the set position between cycle steps from the taper width L. The threshold value is the minimum horizontal movement distance (see FIG. 15B) expected when the peripheral edge of the substrate W moves toward the center of the placing table 32 along the tapered surface 34a in the case where the peripheral edge of the substrate W is located above the tapered surface 34a at the N+1^{th} set position where the substrate W is not mounted. Therefore, if the deviation amount D is greater than the threshold value, it is clear that the substrate W has slid down along the tapered surface 34a, thereby preventing the case in which it is erroneously determined that the substrate W is mounted from occurring.

If the threshold value is set to be less than the taper width L, it is possible to erroneously determine that the actually mounted substrate W′ is not mounted. Hence, the taper width L needs to be as large as possible. In this regard, the taper width L is preferably at least twice the movement distance of the set position between the cycle steps, and more preferably at least three times the movement distance as described in this example (in the above example, the width L of the tapered surface 34a=0.35 mm, and the movement distance of the set position=0.1 mm). As described above, the threshold value to be compared with the deviation amount to determine whether or not the substrate W is mounted on the edge portion 34 is not limited to the width L of the tapered surface 34a adopted in the first embodiment. It may be appropriately adjust and set according to the arrangement state of the equipment, such as the inclination of the placing surface 33 of the placing table 32, and the operation such as the movement direction of the set position along the reference axis M in the cycle step.

Here, in the first cycle step of the second embodiment, in order to ensure the state in which the substrate W′ placed on the placing table 32 is reliably mounted on the edge portion 34, the first set position may be determined as follows, for example. In other words, the first set position may be set to a position where the substrate W is moved horizontally toward the outer periphery of the placing table 32 along the preset reference axis M by the length of “(the diameter of the placing table 32+the taper width L×2)−the diameter of the substrate W″ with respect to the “initial setting position” described with reference to FIG. 11A.

### Modification of Second Embodiment

The present disclosure is not limited to the case of adopting the method in which the boundary position between the tapered surface 34a and the upper end portion 34b is identified using the deviation amount D from the holding positions before and after the substrate W is placed on the placing table 32 as described above. Hereinafter, two examples will be described. In each example, the deviation amount difference Δd between the center positions (c, c′) before and after the placing operation, which is obtained based on the center position c′ of the substrate W measured by the line sensors 41 to 43 after the substrate W is received from the placing table 32 in each cycle step, or the deviation angle difference Δθ between the center positions (c, c′) is used.

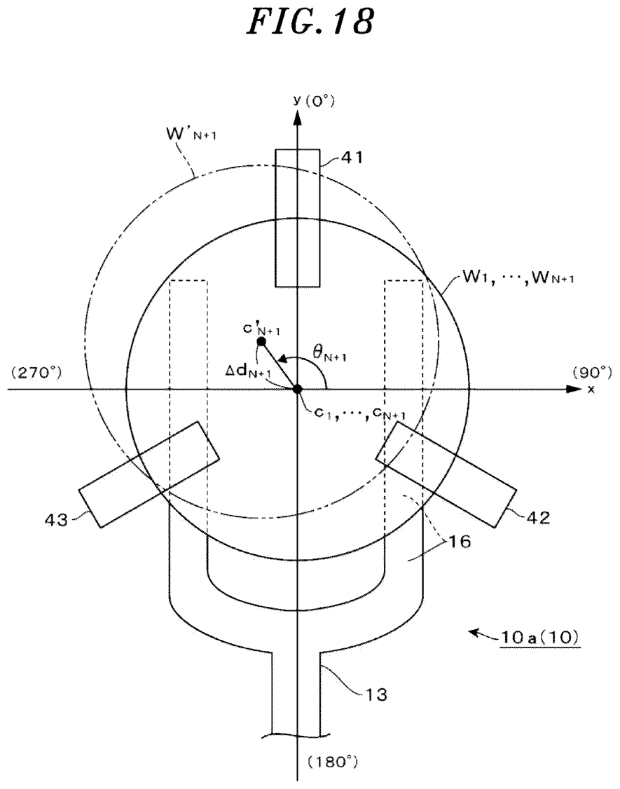

Hereinafter, the first modification in which whether or not the substrate W is mounted is determined based on the deviation amount difference Δd will be described. FIG. 18 shows relative coordinates used in the case of performing the operation of identifying the boundary position, which is common to the first and second modifications of the second embodiment. In FIG. 18, in any n^{th} (n=1, . . . , N, N+1; the same applies below) cycle step, the substrate Wₙ located at the appropriate holding position before the placement on the placing table 32 is indicated by a solid line, and the center cₙ thereof is illustrated. Further, the substrate W′n received from the placing table 32 is indicated by a dashed double-dotted line, and the center c′ₙ thereof is illustrated. Further, in these modifications, the set position is moved from the peripheral side toward the inner side, similarly to the second embodiment described with reference to FIG. 17. The center positions c′₁ to c′_{N} of the substrates W′₁ to W′_{N} received from the placing table 32 in the first to N^{th} cycle steps hardly move because the substrates W′₁ to W′_{N} are mounted on the edge portion 34. Thus, they are located at the same positions as the center positions c₁ to c_{N} of the substrates W′₁ to W′_{N} before the placement on the placing table 32. Accordingly, the substrates W′₁ to W′_{N} received from the placing table 32 are not illustrated in FIG. 18.

In the first modification, the first cycle step is started and, then, in the second and subsequent cycle steps, the deviation difference Δdn, which is the distance between the center positions c′ₙ₋₁ and c′ₙ of the substrates W′ₙ₋₁ and W′ₙ after the placement on the placing table 32 in the current (n^{th}) cycle step and the previous (n−1^{th}) cycle step, is calculated. Similarly to the first embodiment described with reference to FIG. 5, the center positions c′ₙ₋₁ and c′ₙ are calculated from the relative coordinates (xy coordinates in FIG. 18) set with respect to the substrate W aligned in the alignment chamber 26, and the deviation difference Δdn is calculated from the center positions c′ₙ₋₁ and c′ₙ. When the deviation difference Δdn exceeds a preset threshold value in the N+1^{th} cycle step, it is determined that the substrate W_{N+1} has slid down along the tapered surface 34a and is no longer mounted on the edge portion 34.

In the first modification, whether or not the substrate W′ is mounted is determined based on the comparison result of the center positions c′ₙ₋₁ and c′ₙ that are new holding positions of the substrate W′ between the previous cycle step and the subsequent cycle step. The threshold value may be set appropriately according to circumstances, such as the taper width L and the like, as described above. The boundary position is not limited to the case of adopting the N^{th} set position. The boundary position may be a position between the N^{th} set position where the substrate W′ is mounted on the edge portion 34 and the N+1^{th} set position where the substrate W′ is not mounted on the edge portion 34. The method of identifying the boundary position can also be applied to the first embodiment described with reference to FIGS. 8 to 13.

In the determination step of the second modification, the positions of the centers c′ of the substrates W′ at the new holding positions in the previous cycle step and the subsequent cycle step are compared, similarly to in the first modification. In this case, the second modification is different from the first modification in that whether or not the substrate W′ is mounted is determined based on the difference in the movement direction of the center c′. The movement direction of the center c′ is set with the 90° direction along the x-axis of the relative coordinates (xy coordinates) shown in FIG. 18 as the reference direction, for example, and is identified by the deflection angle θ of the deviation direction of the center c′ of the substrate W′ after the placing operation relative to the center c of the substrate W before the placing operation. The deflection angle θ with respect to the x-axis is calculated from Arctan (y/x) based on the value of the center position c′(x, y). Then, based on the deflection angles θₙ₋₁ and θₙ, which are the deviation directions of the center positions c′ₙ₋₁ and c′ₙ between two adjacent cycle steps, the deviation angle difference Δθₙ₊₁ that is the difference between these angles is identified.

In each cycle step, the deviation angle θ of the center c′ is calculated, and in the second and subsequent cycle steps, the deviation angle difference Δθₙ is calculated from the difference between the deviation angle θn of the current (n^{th}) cycle step and the deviation angle θₙ₋₁ of the previous (n−1^{th}) cycle step. Then, if the deviation angle difference Δθₙ exceeds a preset threshold value in the N+1^{th} cycle step, it is determined that the substrate W_{N+1} has slid down along the tapered surface 34a and is no longer mounted on the edge portion 34. The threshold value can be set arbitrarily in consideration of the inclined shape of the placing surface 33, for example, and may be set to ±15 degrees or more, or ±60 degrees or more, for example.

In the second modification described above, the angle difference Δθ in the deviation direction of the center positions c′ₙ₋₁ and c′ₙ between the previous cycle step and the subsequent cycle step was calculated to determine whether or not the substrate W′ is mounted on the edge portion 34. However, it is not necessary to perform the determination based on the deviation angle difference Δθ, and a threshold value may be set in advance for the deviation angle θ calculated in each cycle step, and whether or not the substrate is mounted may be determined based on the result of comparison with the threshold value. The first and second modifications described above are preferably applied to the method of the second embodiment in which the set position of the substrate W is moved from the periphery toward the center of the placing table 32. The first and second modifications may also be applied to the first embodiment in which the set position of the substrate W is moved from the center toward the periphery of the placing table 32. In addition, in the first and second embodiments and the modifications thereof, various calculation methods for detecting the positional deviation of the substrate W on the placing table 32 based on the center position c′ have been described. However, they are merely examples, and the positional deviation of the substrate W may be detected by other calculation methods based on the center position c′.

### Third Embodiment

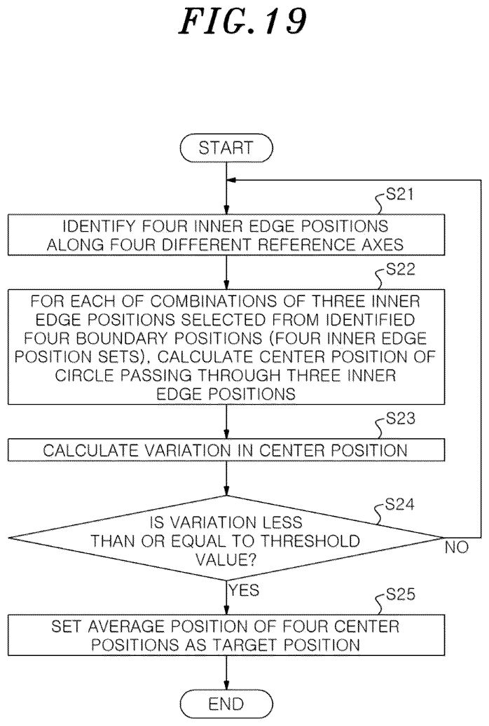

FIG. 19 is a flowchart showing the procedure of the operation of determining a target position in a third embodiment. In the third embodiment, whether or not an abnormal value is included in each boundary position identified in the first and second embodiments is checked, and the target position is precisely set with respect to the center position of the placing table 32. In the third embodiment, the boundary position is identified along four different reference axes, for example, similarly to the first embodiment (step S21). Here, even if whether or not the substrate W′ is mounted is determined by moving the set position from the center toward the periphery as described in the second embodiment, the possibility of erroneous determination exists due to the error that occurs during the transfer operation of the substrate W. Therefore, in the third embodiment, it is determined whether or not an abnormal value is included in the position (hereinafter, also referred to as “inner edge position”) estimated to be the position of the inner edge of the edge portion 34 determined along at least four reference axes.

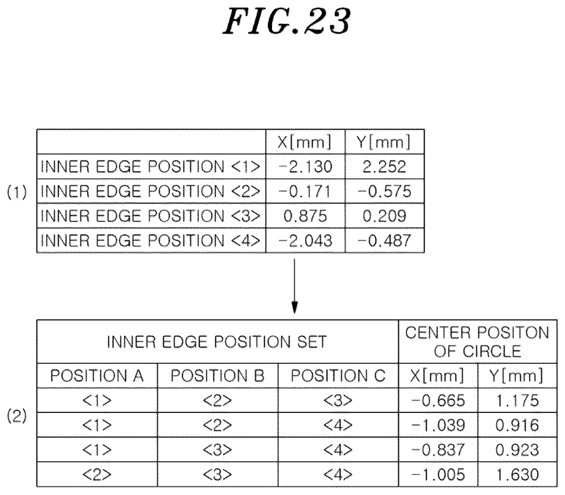

The center position identifying part 51 identifies four inner edge positions along four different reference axes (e.g., the reference axes in the 0°, 90°, 180°, and 270° directions shown in FIGS. 8 and 17) based on the boundary position identifying method described in each of the above-described embodiments (step S21, step of identifying four inner edge positions, Table (1) in FIG. 23). Next, for each of four inner edge position sets, which are combinations of three inner edge positions selected from four inner edge positions, the center position of the circle passing through the three inner edge positions is calculated (step S22, Table (2) in FIG. 23), and the center position of each circle is estimated as the center position of the placing surface 33 (step of estimating the center position of the placing table). Then, the variation in the estimated center position of the placing surface 33 is calculated (step S23).

The variation in the center position can be calculated by various methods. For example, the maximum values dXₘₐₓ and dYₘₐₓ between the X coordinate and the Y coordinate of each center position may be calculated, and the variation in the center position may be calculated using (dXₘₐₓ²+dYₘₐₓ²)^{1/2}. Next, the calculated variation in the center position is compared with a preset threshold value (step S24) to determine whether or not an abnormal value is included the four inner edge positions (step of determining whether or not an abnormal value is included in the inner edge positions). The threshold value is appropriately set as a variation value capable of satisfying desired accuracy by performing a preliminary test or the like in advance.

If the calculated variation in the center position is greater than the preset threshold value (No in step S24), it is considered that an abnormal value is included in any one of the four inner edge positions. In this case, four new reference axes are set instead of the inner edge positions to identify four inner edge positions (step S21). At this time, it is not necessary to newly set all four reference axes, and at least one reference axis may be changed and a new inner edge position may be identified for the changed reference axis. Then, based on the new inner edge position, the above-described steps are repeated until the variation in the center position becomes less than or equal to the threshold value (steps S22 to S24).

If the calculated variation in the center position is less than or equal to the preset threshold value (Yes in step S24), it is determined that an abnormal value is not included in the four inner edge positions, and the average position of the four center positions is set as the target position (step S25). The average position of the center position may be, e.g., the average value of the X coordinate and the Y coordinate of each center position. Alternatively, the target position may be set by selecting an arbitrary center position, or an arbitrary position located inside the four center positions may be selected. Four or more inner edge positions may be identified along four or more reference axes.

### Modification of Third Embodiment

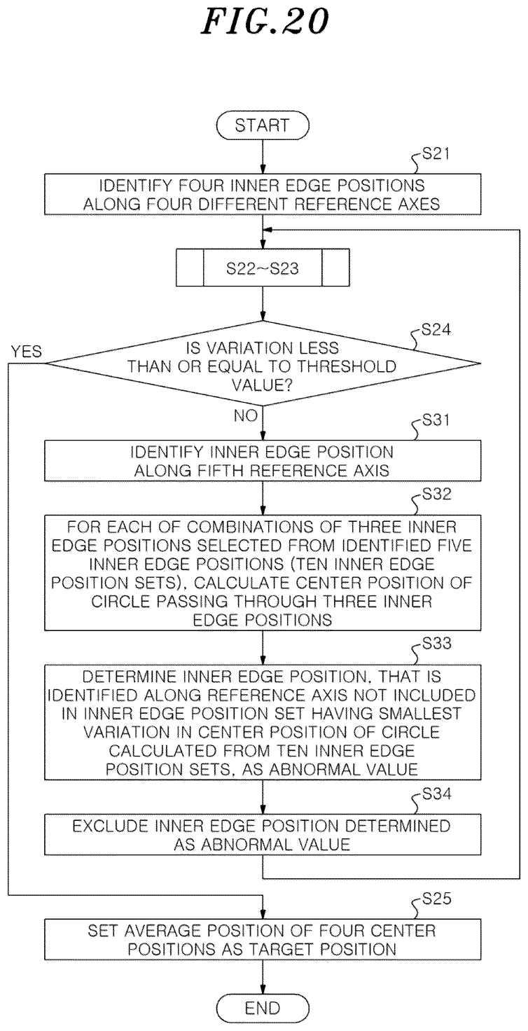

FIG. 20 is a flowchart showing a method for determining a target position according to a modification of the third embodiment. In this modification, the variation in the center position is calculated in the process of the third embodiment (steps S21 to S23). If it is determined that an abnormal value is included in the inner edge position (No in step S24), a cycle is executed along the newly set fifth reference axis to identify a new inner edge position (step S31, step of identifying the fifth inner edge position). The newly identified inner edge position and the four inner edge positions including the abnormal value are used to identify and exclude the inner edge position that is an abnormal value (step S34). These processes are repeated until it is determined that an abnormal value is not included (Yes in step S24). Accordingly, the four inner edge positions that do not include an abnormal value can be efficiently set, and the target position can be set accurately and efficiently at the center position of the placing table 32.

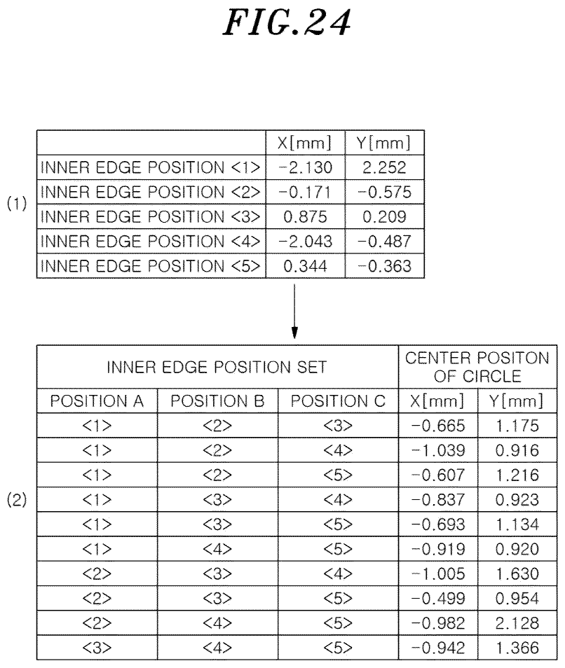

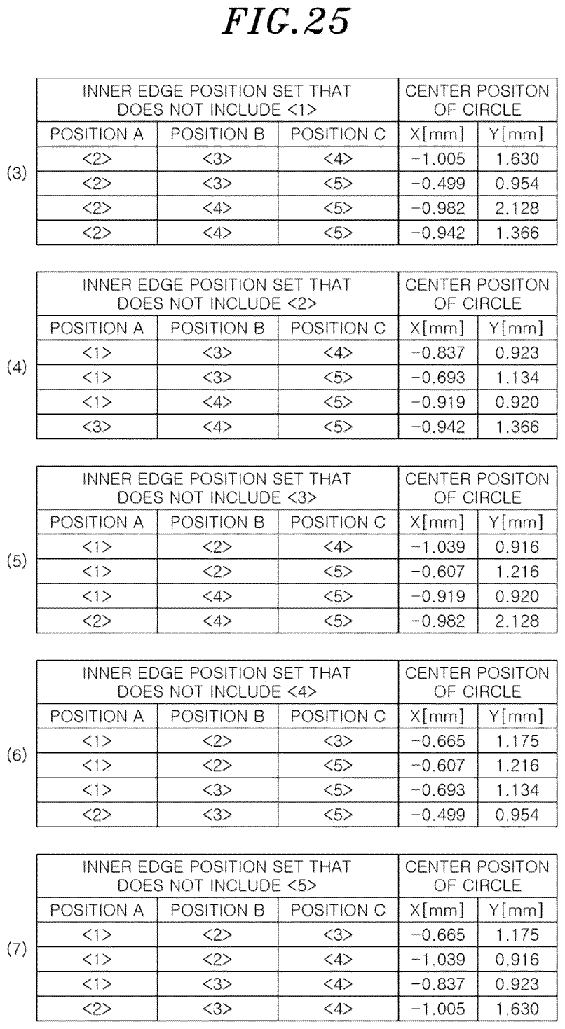

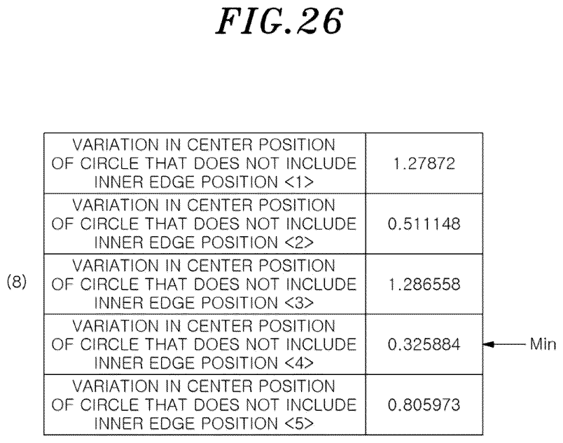

Specifically, in the case of identifying the new inner edge position in step S34, a cycle is executed for the fifth reference axis different from the four reference axes to identify the fifth inner edge position (inner edge position <5> in Table (1) of FIG. 24). Then, for each of ten inner edge position sets, which are combinations of three inner edge positions selected from the four inner edge positions and the fifth inner edge position, the center position of the circle passing through the three inner edge positions is calculated (step S32, Table (2) in FIG. 24). The center position thus identified is estimated as center position of the placing surface 33 (step of estimating the identified center position as the center position of the placing table). Next, among the ten inner edge position sets, four inner edge position sets that do not include any one of the inner edge positions are extracted (Tables (3) to (7) in FIG. 25), and the variation in the center position of each circle is calculated for each combination of the extracted inner edge position sets (Table (8) in FIG. 26).

The variation in the center position of each circle is calculated in the same manner as that in the third embodiment, and the inner edge position that is not included in the combination of the inner edge position sets having the smallest variation is determined to be an abnormal value (step S33, step of determining an inner edge position as an abnormal value, Table (8) in FIG. 26). Then, for the other four inner edge positions except the inner edge position determined to be an abnormal value, the above-described steps S22 to S24 are performed again to determine whether or not an abnormal value is included the four inner edge positions. If it is determined that an abnormal value is not included (Yes in step S24), a target position is set in the same manner (step S25) as that in the third embodiment. If it is determined that an abnormal value is included (No in step S24), a new fifth reference axis is set again and steps S31 to S34 are performed to identify and exclude the abnormal values from the five inner edge positions. The above steps S22 to S24 and S31 to S34 are repeated until it is determined that an abnormal value is not included (Yes in step S24). As described above, in this modification, the addition of the fifth inner edge position and the exclusion of the inner edge position determined as an abnormal value are repeated until it is determined that no abnormal value is included in the four inner edge positions, and the target position can be set by the inner edge position from which an abnormal value is excluded.

### TEST EXAMPLES

### Test 1

The teaching of the set position shown in the first embodiment was performed.

### A. Test Conditions

By using the same substrate processing apparatus 1 as that in the first embodiment, the initial setting position was set, and the set position in the boundary position identifying operation in each of the reference directions of 0°, 180°, 90°, and 270° was moved by 0.1 mm. Then, the deviation amount was calculated for each position. Whether or not the substrate is mounted was determined by comparing the deviation amount D at each set position with the threshold value that is the width L of the tapered surface 34a, and the coordinates of the set position of the holding part 16 were plotted. The coordinates were plotted as differential coordinates with respect to the initial setting position so that the initial setting position becomes the origin.

### B. Test Results

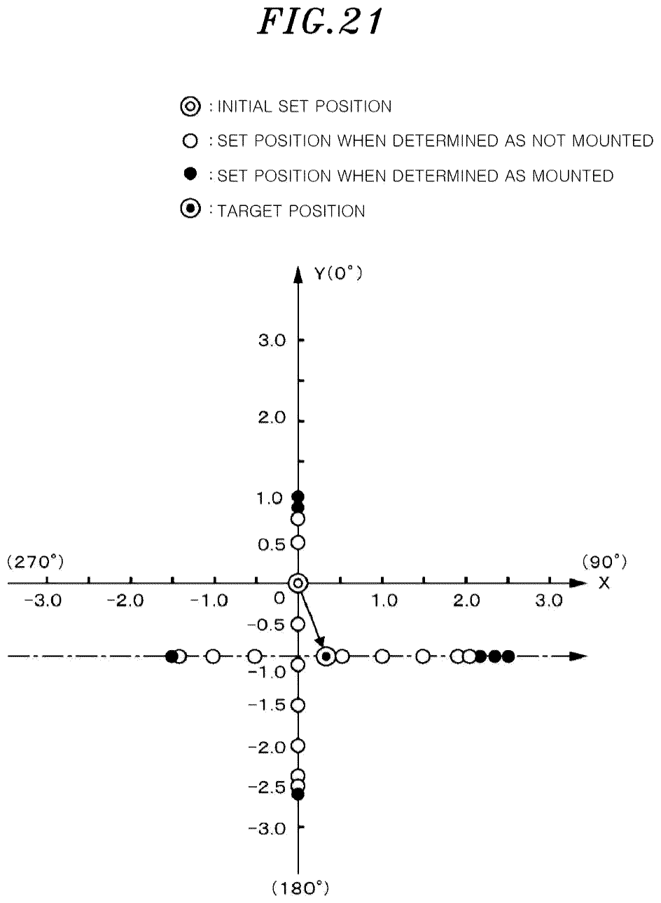

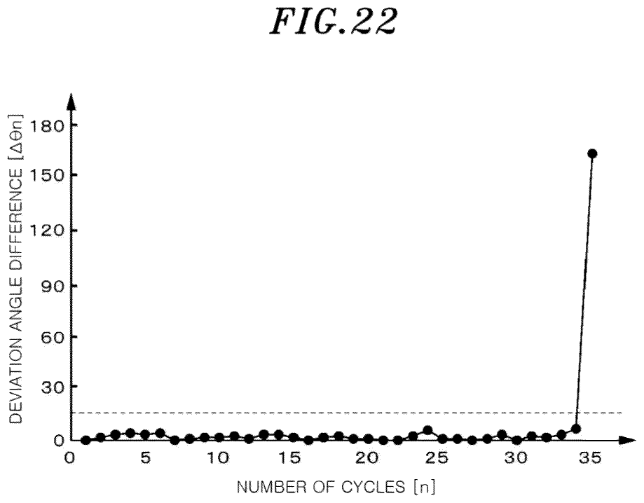

FIG. 21 shows the differential coordinates for each set position with respect to the initial set position, and some plots are omitted for convenience of illustration. For each set position in the 0° direction, it was determined that the substrate was not mounted when the Y coordinate was between 0 mm and 0.8 mm, and it was determined that the substrate was mounted when the Y coordinate was 0.9 mm and 1.0 mm. The set position where the Y coordinate was 0.9 mm was determined as the boundary position, and the displacement amount δ1 was 0.9 mm. For each set position in the 180° direction, it was determined that the substrate was not mounted when the Y coordinate was between −0.1 mm and −2.5 mm, and it was determined that the substrate was mounted when the Y coordinate was −2.6 mm. The set position where the Y coordinate was −2.6 mm was determined as the boundary position, and the displacement δ2 was −2.6 mm. The Y coordinate of the target position was obtained as 0+(δ1+δ2)/2=(0.9−2.6)/2=−0.85 mm, and this was set as the Y coordinate of each set position in the 90° and 270° directions.

For each set position in the 90° direction, it was determined that the substrate was not mounted when the X coordinate was between +0.1 mm and 2.0 mm, and it was determined that the substrate was mounted when the Y coordinate was 2.1 mm, 2.2 mm, and 2.3 mm. The set position where the X coordinate was 2.1 mm was determined as the boundary position, and the displacement amount δ3 was 2.1 mm. For each set position in the 270° direction, it was determined that the substrate was not mounted when the X coordinate was between −0.1 mm and −1.4 mm, and it was determined that the substrate was mounted when the X coordinate was −1.5 mm. The set position where the X coordinate was −1.5 mm was determined as the boundary position, and the displacement amount δ4 was −1.5 mm. The X coordinate of the target position was obtained as 0+(δ3+θ4)/2=(2.1−1.5)/2=0.3 mm. The target position (0.3, −0.85) determined as described above was reset as the set position, and the holding part 16 was placed at the set position. Accordingly, it was visually confirmed that the center C of the substrate W held at the holding position was located on the center P of the placing surface 33. Then, the substrate W placed on the placing table 32 via the lift pins 38 was located within the placing surface 33.

### Test 2

The tendency of the deviation angle difference Δθ shown in the second modification of the second embodiment was checked to verify whether or not it is possible to identify the boundary position using the modification.

### A. Test Conditions

As described above in the second modification, each set position is moved from the center toward the periphery of the placing surface 33 along one reference axis, and the center position c′ of the substrate W′ received from the placing table 32 is measured by the line sensors 41 to 43 in each cycle step. Then, the deviation angle θ, which is the deflection angle of each center position c′, is calculated, and the deviation angle difference Δθ between the previous cycle and the subsequent cycle is calculated. The threshold value of the deviation angle difference Δθ is set to 15°.

### B. Test Results

FIG. 22 is a graph showing the test results of Test 2. The horizontal axis represents the number of cycles n, and the vertical axis represents the deviation angle difference Δθₙ. For convenience of calculation, when the number of cycle was 0, the deviation angle θ was set to 0°. As shown in FIG. 22, when n was between 1 and 34, the deviation angle difference Δθₙ was stable and less than ±5°. Therefore, when n was between 1 and 34, it was estimated that the deflection angles of the central positions c′ₙ₋₁ and c′ₙ between the previous cycle step and the subsequent cycle step were close to 0° and substantially the same, and it was considered that each central position c′ was substantially the same as the corresponding central position c. When n was 35, the deviation angle difference Δθₙ was 165°, which was considerably greater than the threshold value of 15°. Hence, it was estimated that the deflection angle of the central position c′35 (n=35) was close to 165°, which was moved considerably from the corresponding central position c₃₅. From the above, it was estimated that the boundary position was the set position in the 34^{th} cycle. N

### Test 3

The four inner edge positions were identified using the second embodiment, and the degree of variation in each central position calculated using the three inner edge positions constituting the four inner edge position sets according to the third embodiment was checked.

### A. Test Conditions

The three boundary positions were identified without erroneous determination by the boundary position identifying operation described in the second embodiment, and one boundary position was intentionally erroneously determined as an abnormal value by using the boundary position identifying operation described in the first embodiment, thereby identifying the four inner edge positions. The center position of each circle was calculated for combinations of the four boundary position sets in which the three inner edge positions were selected four the inner edge positions, and the variation in the center positions of the four circles in the case where one abnormal value was included was calculated.

### B. Test Results

FIG. 23 shows Tables (1) and (2) showing the test results of Test 4. Table (1) of the second embodiment shows the coordinates of the four inner edge positions <1> to <4>. The inner edge positions <1> to <3> were identified without erroneous determination, and the inner edge position <4> was intentionally identified by erroneous determination. As shown in Table (2) of FIG. 23, four inner edge position sets were obtained by selecting three inner edge positions among the inner edge positions <1> to <4>, and the center positions of the circles passing through the three inner edge positions of each set were calculated from the coordinates of each inner edge position. In order to calculate the variation in the center positions of the circles, first, the maximum value dXₘₐₓ=−1.039−(−0.665)=0.374 mm of the difference in the X coordinates of the center positions and the maximum value dYₘₐₓ=1.630−0.916=0.714 mm of the difference in the Y coordinates thereof were obtained. Using these values, the variation in the center positions of the circles was calculated as (dXₘₐₓ²+dYₘₐₓ²)^{1/2}=(0.374²+0.714²)^{1/2}=0.806 mm.

As described above, by collecting the variation in the center positions of the circles in which the four boundary positions including one abnormal value are identified, and the variation in the center positions of the circles in which the four inner edge positions that do not include an abnormal value are identified, it was possible to obtain a threshold value for the variation in the center positions for determining whether or not an abnormal value is included in the inner edge position.

### Test 4

Whether or not an abnormal value can be detected by the modification of the third embodiment is checked.

### A. Test Conditions

Ten inner edge position sets and the center positions of the circles were identified by the four boundary positions <1> to <4> including one abnormal value in Test 4 and the newly identified boundary position <5> that was not an abnormal value. Then, among the ten inner edge position sets, the combinations of four inner edge position sets that do not include the respective inner edge positions were extracted, and the variation in the center positions of the circles in each combination was calculated. The inner edge position that was not included in the four inner edge position sets having the smallest variation was identified, and whether or not the inner edge position <4> can be identified as an abnormal value was checked.

### B. Test Results

FIGS. 24 to 26 are tables showing the test results of Test 4. Table (1) in FIG. 24 shows the coordinates of the four inner edge positions <1> to <4> and the inner edge position <5> that is not an abnormal value in Test 4. As shown in Table (2) in FIGS. 24 to 26, ten inner edge position sets were obtained by selecting three inner edge positions among the inner edge positions <1> to <5>, and the center position of the circle passing through the three inner edge positions in each set was calculated from the coordinates of each inner edge position. Among the inner edge position sets, four inner edge position sets that do not include the inner edge positions <1> to <5> were extracted (Tables (3) to (7) in FIG. 25). The variation in the center positions of the circles for each inner edge position set that does not include the inner edge positions <1> to <5> was calculated, similarly to the variation in the center positions of the circles in test 4 (Table (8) in FIG. 26). Among them, it was possible to identify the inner edge position <4> that is an abnormal value and having the smallest variation in the center positions of the circles for the inner edge position sets that do not include the inner edge position <4>.

Further, it should be noted that the embodiments of the present disclosure are illustrative in all respects and are not restrictive. The above-described embodiments can be may be omitted, replaced, or changed in various forms without departing from the scope of the appended claims and the gist thereof.

1. A teaching method for a substrate transfer device, wherein the substrate device includes a transfer arm configured to transfer a substrate, a driving mechanism configured to move the transfer arm, and a driving controller configured to control the driving mechanism such that the transfer arm moves to a set position that is preset in advance, and
wherein a placing table has a placing surface on which the substrate is placed, an edge portion that protrudes from the placing surface along a periphery of the placing surface, and a lift pin configured to protrude and retract with respect to the placing surface and transfer the substrate between the placing surface and the transfer arm,
when the substrate is transferred by the transfer arm with respect to the placing table, the method comprises:
moving the set position multiple times along one reference axis selected from a plurality of reference axes, which are set to pass through a center and a periphery of the placing surface and extend in different directions, and executing, at each set position, a cycle including the following steps (a) to (d):
(a) moving the transfer arm holding the substrate at a preset holding position toward one set position;
(b) transferring the substrate from the transfer arm that has moved to the one set position to the placing table via the lift pin;
(c) receiving the substrate by the transfer arm, from the placing table to which the substrate has been transferred, via the lift pin; and
(d) detecting a new holding position of the substrate after the substrate is received by the transfer arm from the placing table;
determining whether or not the substrate was mounted on the edge portion in step (b) of the cycle, based on the new holding position detected in step (d);
specifying a target position where the substrate is transferred from the transfer arm to the placing table, based on the one set position for each of the plurality of reference axes when it is determined that the substrate was mounted on the edge portion; and
causing the driving controller to set the target position as the set position of the transfer arm.

2. The method of claim 1, wherein in said determining, if a deviation amount between the preset holding position and the new holding position of the substrate detected in step (d) is less than or equal to a preset threshold value, it is determined that the substrate was mounted on the edge portion in step (b) of the cycle.

3. The method of claim 2, wherein in said executing the cycle, the set position is moved from the center toward the periphery along the one reference axis based on a preset movement distance, and the cycle is repeated until the deviation amount detected in step (d) becomes less than or equal to the threshold value.

4. The method of claim 2, wherein in said executing the cycle, the set position is moved from the periphery toward the center along the one reference axis based on a preset movement distance, and the cycle is repeated until the deviation amount detected in step (d) becomes greater than the threshold value.

5. The method of claim 1, wherein in said determining, whether or not the substrate was mounted on the edge portion is determined based on a result of comparing the new holding positions of the substrate detected in step (d) between two cycles executed before and after the set position is moved.

6. The method of claim 5, wherein in said determining, whether or not the substrate was mounted on the edge portion is determined based on a distance between centers of the substrate at the new holding positions of the substrate between the two cycles.

7. The method of claim 6, wherein in said executing the cycle, the set position is moved from the periphery toward the center along the one reference axis based on a preset movement distance, and
in said determining, the cycle is repeated until the distance between the centers of the substrate at the new holding positions of the substrate between the two cycles becomes greater than a preset threshold value.

8. The method of claim 5, wherein in said determining, whether or not the substrate was mounted on the edge portion is determined based on a difference between directions in which a center of the substrate moves at the new holding positions of the substrate between the two cycles.

9. The method of claim 8, wherein in said executing the cycle, the set position is moved from the periphery toward the center along the one reference axis based on a preset movement distance, and
in said determining, the cycle is repeated until a difference between angles of deviation directions of the center of the substrate at the new holding positions of the substrate between the two cycles becomes greater than a preset threshold value.

10. The method of claim 1, wherein the placing table has a circular planar shape, and the plurality of reference axes are set to be at least three.

11. The method of claim 3, wherein the substrate has a circular planar shape, and
in said specifying the target position, the target position is determined such that a center of the substrate coincides with a center of the placing table.

12. The method of claim 11, wherein in said executing the cycle, the cycle is executed along four reference axes, and
said specifying the target position includes:
identifying four inner edge positions estimated as inner edge positions of the edge portion, based on the one set position when it is determined that the substrate was mounted on the edge portion from the result of executing the cycle along each of the four reference axes;
identifying, for each of four inner edge position sets which are combinations of three inner edge positions selected from the four inner edge positions, a position of a center of a circle passing through the three inner edge positions, and estimating a center position of the placing table, and
comparing a variation in the center position of the placing table estimated from the four inner edge position sets with a preset threshold value, and determining whether or not an abnormal value is included in the inner edge positions.

13. The method of claim 12, further comprising:
executing, when it is determined in said determining that the abnormal value is included in the inner edge positions, the cycle for a fifth reference axis different from the four reference axes and identifying a fifth inner edge position, and
said specifying the target position includes:
identifying, for each of ten inner edge position sets which are combinations of three inner edge positions selected from the four inner edge positions and the fifth inner edge position, a position of a center of a circle passing through the three inner edge positions, and estimating a center position of the placing table; and
determining, as the abnormal value, the inner edge position identified along the reference axis that is not included in the inner edge position set in which a variation in the center position of the placing table estimated from the ten inner edge position sets is smallest.

14. The method of claim 13, wherein in said specifying the target position, a step of estimating the center position of the placing table is performed with respect to remaining four inner edge positions excluding the inner edge position determined as the abnormal value, and a step of determining whether or not an abnormal value is included in the inner edge positions is performed.

15. The method of claim 1, wherein the substrate has a circular planar shape, and
in step (d), a center of the substrate held by the transfer arm is obtained and a new holding position of the substrate is detected.

16. The method of claim 15, wherein in step (d), a center position of the substrate is obtained based on a result of detecting positions of at least three different points along the periphery of the substrate held by the transfer arm.

17. The method of claim 1, wherein a tapered surface that is gradually lowered from an upper end of the edge portion toward the placing surface is formed on an inner periphery of the edge portion that faces the placing surface.

18. The method of claim 1, wherein the placing table is provided in a processing chamber for processing the substrate.

19. The method of claim 18, wherein the processing chamber constitutes a film forming module for performing a film forming process on the substrate.

20. The method of claim 18, wherein the teaching method is performed during a period in which the substrate is not processed.

21. A substrate processing apparatus for processing a substrate, comprising:
a processing module having a processing chamber for processing a substrate;
a transfer module having a transfer arm configured to transfer the substrate;
a position detection mechanism configured to detect a position of the substrate held by the transfer arm; and
a controller;
wherein a placing table having a placing surface on which a substrate is placed, an edge portion that protrudes from the placing surface along a periphery of the placing surface, and a lift pin configured to protrude and retract with respect to the placing surface and transfer the substrate between the placing surface and the transfer arm is provided in the processing chamber, and
when the substrate is transferred by the transfer arm, the controller is configured to output a control signal for executing steps including:
moving a set position multiple times along one reference axis selected from a plurality of reference axes, which are set to pass through a center and a periphery of the placing surface and extend in different directions, and executing, at each set position, a cycle including the following steps (a) to (d):
(a) moving the transfer arm holding the substrate at a preset holding position toward one set position;
(b) transferring the substrate from the transfer arm that has moved to the one set position to the placing table via the lift pin;
(c) receiving the substrate, by the transfer arm, from the placing table to which the substrate has been transferred, via the lift pin; and
(d) detecting a new holding position of the substrate after the substrate is received by the transfer arm from the placing table;
determining whether or not the substrate was mounted on the edge portion in step (b) of the cycle based on the new holding position detected in step (d);
determining a target position where the substrate is transferred from the transfer arm to the placing table, based on the one set position for each of the plurality of reference axes when it is determined that the substrate was mounted on the edge portion; and
setting the target position as the set position of the transfer arm.
